(19) United States
(12) Patent Application Publication
(10) Pub. No.: US 2025/0063757 A1
(43) Pub. Date: Feb. 20, 2025

(54) SEMICONDUCTOR DEVICE AND ELECTRONIC DEVICE

(71) Applicant: SONY SEMICONDUCTOR SOLUTIONS CORPORATION, KANAGAWA (JP)

(72) Inventors: RYOHEI TAKAYANAGI, KANAGAWA (JP); AKIKO HONJO, KANAGAWA (JP)

(21) Appl. No.: 18/718,105

(22) PCT Filed: Dec. 2, 2022
(86) PCT No.: PCT/JP2022/044593

§ 371 Date: Jun. 10, 2024

(30) Foreign Application Priority Data
Dec. 17, 2021 (JP) 2021-205244

(51) Int. Cl. H01L 29/78; H01L 27/146; H01L 29/417; H01L 29/423; H01L 29/66; H01L 29/786

(52) U.S. Cl. CPC H01L 29/785; H01L 29/41791; H01L 29/42356; H01L 29/78696; H01L 27/14643; H01L 29/66795

(57) ABSTRACT

The occurrence of a short-channel effect is suppressed. A semiconductor device includes a semiconductor layer having an upper surface portion, a lower surface portion, and a side surface portion, and a field-effect transistor in which a channel forming portion is provided in the semiconductor layer. The field effect transistor includes a gate electrode provided in the channel forming portion of the semiconductor layer over the upper surface portion and the side surface portion of the semiconductor layer with a gate insulating film interposed therebetween, and a pair of main electrode regions provided on an outer side of the semiconductor layer in a channel length direction of the channel forming portion and separated from each other with the channel forming portion interposed therebetween. Each of the pair of main electrode regions includes a conductor layer that is provided in contact with the side surface portion of the semiconductor layer and that is in a layer different from the semiconductor layer.

### TECHNICAL FIELD

The present technology (technology according to the present disclosure) relates to a semiconductor device and an electronic device, and particularly relates to a technology that is effective when applied to a semiconductor device having a fin-type field effect transistor and an electronic device having the same.

### BACKGROUND ART

As a field-effect transistor mounted on a semiconductor device, a field-effect transistor (FinFET) with an SOI (Silicon On Insulator)-Fin structure, whose channel forming portion is an island-shaped semiconductor layer provided on an insulating film, is known.

Further, as a semiconductor device, for example, a solid-state imaging device called a CMOS image sensor is known. This CMOS image sensor is equipped with a readout circuit that reads out signal charges photoelectrically converted by a photoelectric conversion element. The readout circuit includes pixel transistors such as an amplification transistor, a selection transistor, and a reset transistor.

By using a field effect transistor with an SOI-Fin structure for such a pixel transistor, it is possible to improve DC characteristics.

However, even in a field effect transistor with an SOI-Fin structure, if a region that is not depleted (non-depletion region) occurs on the lower surface portion side of a semiconductor layer (lower portion of a channel-forming region), charges are accumulated in the non-depletion region. Thus, there is a concern that this may lead to a phenomenon in which the characteristics become unstable (Partially Depletion: PD) (NPL 1).

### CITATION LIST

### Non Patent Literature

[NPL 1] W. Xiong, et.al., “Full/partial depletion effects in FinFETs”, IEEE International SOI Conference, Oct. 4, 2004

### SUMMARY

### Technical Problem

Therefore, in order to prevent PD in a field effect transistor with an SOI-Fin structure, it is preferable that a pair of main electrode regions that functions as a source region and a drain region is formed to a depth extending from an upper surface portion side of a semiconductor layer to a lower surface portion side (bottom surface portion side).

However, when attempting to form a pair of semiconductor regions by implanting impurity ions to a depth extending from the upper surface portion side of the semiconductor layer to the lower surface portion side (bottom surface portion side), it is necessary to implant impurity ions with higher acceleration energy. This causes impurities to enter unnecessary regions due to lateral diffusion, shortening the effective channel length and making a short-channel effect more likely to occur. The occurrence of this short-channel effect deteriorates the characteristics of field effect transistors and impedes miniaturization, so there is room for improvement.

An object of the present technology is to suppress the occurrence of a short-channel effect.

### Solution to Problem

(1) A semiconductor device according to an aspect of the present technology includes a semiconductor layer having an upper surface portion, a lower surface portion, and a side surface portion, and a field effect transistor in which a channel forming portion is provided in the semiconductor layer. The field-effect transistor includes a gate electrode provided in the channel forming portion of the semiconductor layer over the upper surface portion and the side surface portion of the semiconductor layer with a gate insulating film interposed therebetween, and a pair of main electrode regions provided on an outer side of the semiconductor layer in a channel length direction of the channel forming portion and separated from each other with the channel forming portion interposed therebetween. Each of the pair of main electrode regions includes a conductor layer that is provided in contact with the side surface portion of the semiconductor layer and that is in a layer different from the semiconductor layer.

(2) An electronic device according to another aspect of the present technology includes the semiconductor device, an optical lens that forms an image of image light from a subject onto an imaging surface of the semiconductor device, and a signal processing circuit that performs signal processing on signals output from the semiconductor layer.

### BRIEF DESCRIPTION OF DRAWINGS

FIG. 1 is a schematic plan view showing a configuration example of a semiconductor device according to a first embodiment of the present technology.

FIG. 2 is a schematic vertical cross-sectional view showing a vertical cross-sectional structure taken along the cutting line a1-a1 in FIG. 1.

FIG. 3 is a schematic vertical cross-sectional view showing a vertical cross-sectional structure taken along the cutting line b1-b1 in FIG. 1.

FIG. 4 is a diagram showing the steps of the method for manufacturing a semiconductor device according to the first embodiment of the present technology (in which FIG. 4(a) is a schematic plan view, FIG. 4(b) is a schematic vertical cross-sectional view at the same position as the cutting line a1-a1 in FIG. 1, and FIG. 4(c) is a schematic vertical cross-sectional view at the same position as the cutting line b1-b1 in FIG. 1).

FIG. 5 is a diagram showing the steps subsequent to FIG. 4 (in which FIG. 5(a) is a schematic plan view, FIG. 5(b) is a schematic vertical cross-sectional view at the same position as the cutting line a1-a1 in FIG. 1, and FIG. 5(c) is a schematic vertical cross-sectional view at the same position as the cutting line b1-b1 in FIG. 1).

FIG. 6 is a diagram showing the steps subsequent to FIG. 5 (in which FIG. 6(a) is a schematic plan view, FIG. 6(b) is a schematic vertical cross-sectional view at the same position as the cutting line a1-a1 in FIG. 1, and FIG. 6(c) is a schematic vertical cross-sectional view at the same position as the cutting line b1-b1 in FIG. 1).

FIG. 7 is a diagram showing the steps subsequent to FIG. 6 (in which FIG. 7(a) is a schematic plan view, FIG. 7(b) is a schematic vertical cross-sectional view at the same position as the cutting line a1-a1 in FIG. 1, and FIG. 7(c) is a schematic vertical cross-sectional view at the same position as the cutting line b1-b1 in FIG. 1).

FIG. 8 is a diagram showing the steps subsequent to FIG. 7 (in which FIG. 8(a) is a schematic plan view, FIG. 8(b) is a schematic vertical cross-sectional view at the same position as the cutting line a1-a1 in FIG. 1, and FIG. 8(c) is a schematic vertical cross-sectional view at the same position as the cutting line b1-b1 in FIG. 1).

FIG. 9 is a diagram showing the process subsequent to FIG. 8 (in which FIG. 9(a) is a schematic plan view, FIG. 9(b) is a schematic vertical cross-sectional view at the same position as the cutting line a1-a1 in FIG. 1, and FIG. 9(c) is a schematic vertical cross-sectional view at the same position as the cutting line b1-b1 in FIG. 1).

FIG. 10 is a diagram showing the steps subsequent to FIG. 9 (in which FIG. 10(a) is a schematic plan view, FIG. 10(b) is a schematic vertical cross-sectional view at the same position as the cutting line a1-a1 in FIG. 1, and FIG. 10(c) is a schematic vertical cross-sectional view at the same position as the cutting line b1-b1 in FIG. 1).

FIG. 11 is a diagram showing the steps subsequent to FIG. 10 (in which FIG. 11(a) is a schematic plan view, FIG. 11(b) is a schematic vertical cross-sectional view at the same position as the cutting line a1-a1 in FIG. 1, and FIG. 11(c) is a schematic vertical cross-sectional view at the same position as the cutting line b1-b1 in FIG. 1).

FIG. 12 is a diagram showing the steps subsequent to FIG. 11 (in which FIG. 12(a) is a schematic plan view, FIG. 12(b) is a schematic vertical cross-sectional view at the same position as the cutting line a1-a1 in FIG. 1, and FIG. 12(c) is a schematic vertical cross-sectional view at the same position as the cutting line b1-b1 in FIG. 1).

FIG. 13 is a schematic vertical cross-sectional view showing a comparative example.

FIG. 14 is a schematic cross-sectional view showing a configuration example of a semiconductor device according to a second embodiment of the present technology.

FIG. 15 is a schematic vertical cross-sectional view showing the steps of the method for manufacturing a semiconductor device according to the second embodiment of the present technology.

FIG. 16 is a schematic vertical cross-sectional view showing a step subsequent to FIG. 15.

FIG. 17 is a schematic vertical sectional view showing a modified example of the second embodiment.

FIG. 18 is a schematic plan view showing a configuration example of a semiconductor device according to a third embodiment of the present technology.

FIG. 19 is a schematic vertical cross-sectional view showing a vertical cross-sectional structure taken along the cutting line a18-a18 in FIG. 18.

FIG. 20 is a schematic vertical cross-sectional view showing the steps of the method for manufacturing a semiconductor device according to the third embodiment of the present technology.

FIG. 21 is a schematic vertical cross-sectional view showing a step subsequent to FIG. 20.

FIG. 22 is a schematic plan view showing a configuration example of a semiconductor device according to a fourth embodiment of the present technology.

FIG. 23 is a schematic vertical cross-sectional view showing a vertical cross-sectional structure taken along cutting line a22-a22 in FIG. 22.

FIG. 24 is a schematic vertical cross-sectional view showing the steps of the method for manufacturing a semiconductor device according to the fourth embodiment of the present technology.

FIG. 25 is a schematic vertical sectional view showing a step subsequent to FIG. 24.

FIG. 26 is a schematic vertical cross-sectional view showing a configuration example of a semiconductor device according to a fifth embodiment of the present technology.

FIG. 27 is a schematic vertical cross-sectional view showing a configuration example of a semiconductor device according to a sixth embodiment of the present technology.

FIG. 28 is a schematic plan layout diagram showing a configuration example of a solid-state imaging device according to a seventh embodiment of the present technology.

FIG. 29 is a block diagram showing a configuration example of a solid-state imaging device according to the seventh embodiment of the present technology.

FIG. 30 is an equivalent circuit diagram showing a configuration example of a pixel and a readout circuit of a solid-state imaging device according to the seventh embodiment of the present technology.

FIG. 31 is a schematic vertical cross-sectional view of a main part showing a vertical cross-sectional structure of a pixel region.

FIG. 32 is a schematic vertical cross-sectional view showing a configuration example of a semiconductor device according to an eighth embodiment of the present technology.

FIG. 33 is a diagram showing a schematic configuration of an electronic device according to a ninth embodiment of the present technology.

FIG. 34A is a schematic plan view showing a configuration example of a field-effect transistor according to another embodiment of the present technology.

FIG. 34B is a schematic plan view showing a configuration example of a field-effect transistor according to another embodiment of the present technology.

### DESCRIPTION OF EMBODIMENTS

Embodiments of the present technology will be described below with reference to the drawings.

In the descriptions of the drawings referred to in the following description, the same or similar portions will be denoted by the same or similar reference signs. However, it should be noted that the drawings are schematic, and the relationships between thicknesses and planar dimensions, ratios of thicknesses of respective layers, and the like are different from actual ones. Therefore, specific thicknesses and dimensions should be determined by considering the following descriptions.

In addition, it goes without saying that the drawings further include portions having dimensional relationships and ratios different from each other.

Furthermore, the advantageous effects described in the present specification are merely exemplary and not intended as limiting, and other advantageous effects may be produced.

In addition, the following embodiments exemplify devices and methods for embodying the technical ideas of the present technology, and the configurations are not limited to those described below. That is, the technical ideas of the present technology can be variously modified within the technical scope described in the claims.

In addition, it is to be understood that definitions of directions such as a vertical direction in the following descriptions are merely definitions provided for convenience of explanation and do not limit the technical idea of the present technology. For example, it is obvious that when a target is rotated 90° and observed, the top and bottom will be converted to the left and right and, obviously, if the target is rotated 180° and observed, the top and bottom will be read as reversed.

Further, in the following embodiments, a case where the first conductivity type is p-type and the second conductivity type is n-type will be exemplified as the conductivity type of the semiconductor. However, if the conductivity types are selected in the opposite relationship, the first conductivity type may be n-type and the second conductivity type may be p-type.

In the following embodiment, in the three directions orthogonal to each other in a space, a first direction and a second direction orthogonal to each other in the same plane are set to an X direction and a Y direction, respectively, and a third direction orthogonal to each of the first direction and the second direction is defined as a Z direction. In the following embodiments, the thickness direction of the semiconductor layer 3, which will be described later, will be described as the Z direction.

### First Embodiment

In the first embodiment, an example in which the present technology is applied to a semiconductor device having a field effect transistor will be described.

### <<Configuration of Semiconductor Device>>

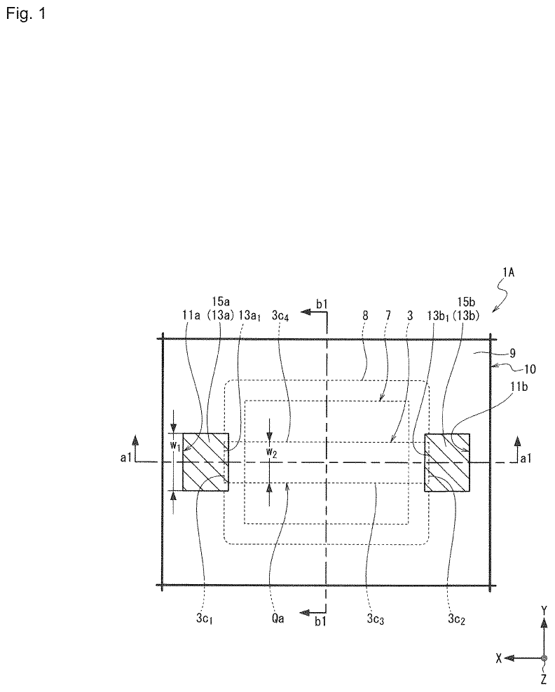

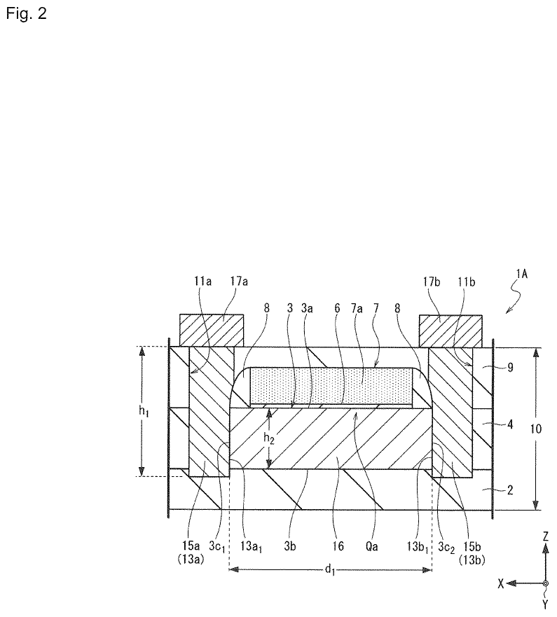

First, the overall configuration of a semiconductor device 1A will be described using FIGS. 1, 2, and 3. In FIG. 1, for convenience of explanation, wirings 17a and 17b shown in FIG. 2 are not shown.

As shown in FIGS. 1, 2, and 3, the semiconductor device 1A according to the first embodiment of the present technology includes an island-shaped semiconductor layer 3, a field effect transistor Qa having a channel forming portion (channel region) 16 provided in the semiconductor layer 3, and an insulating layer 10 that includes the semiconductor layer 3 and the field effect transistor Qa.

### <Semiconductor Layer>

As shown in FIGS. 1 to 3, the semiconductor layer 3 is formed of a rectangular parallelepiped having, for example, an upper surface portion 3a, a lower surface portion 3b, and four side surface portions 301, 302, 303, and 304. The semiconductor layer 3 extends in the X direction, for example. The upper surface portion 3a and the lower surface portion 3b are located on opposite sides of the semiconductor layer 3 in the thickness direction (Z direction). Among the four side surface portions 301, 302, 3c3, and 3c4, two side surface portions 301 and 3c₂ are located on opposite sides in the X direction, and the remaining two side surface portions 3c₃ and 3c₄ are located on opposite sides in the Y direction.

The semiconductor layer 3 is made of, but not limited to, for example, silicon (Si) as a semiconductor material, a single crystal as a crystallinity, and an i-type (intrinsic type) as a conductivity type. That is, the semiconductor layer 3 is made of i-type single-crystal silicon.

### <Insulating Layer>

The insulating layer 10 has a multilayer structure including a first insulating film (base insulating film) 2 provided in contact with the lower surface portion 3b on the lower surface portion 3b side of the semiconductor layer 3 opposite to the upper surface portion 3a, a second insulating film (surrounding insulating film) 4 provided on the first insulating film 2 to surround the semiconductor layer 3, and a third insulating film (covering insulating film) 9 provided on the second insulating film 4 to cover the semiconductor layer 3 and a gate electrode 7 to be described later. Each of the first insulating film 2, the second insulating film 4, and the third insulating film 9 is made of, for example, a silicon oxide (SiO₂) film. That is, the semiconductor device 1A of the first embodiment has an SOI (Silicon On Insulator) structure in which the semiconductor layer 3 of silicon (Si) is provided on the first insulating film 2.

### <Field-Effect Transistor>

The field effect transistor Qa is, for example, of an n-channel conductivity type, although it is not limited thereto. The field effect transistor Qa is configured with a MOSFET (Metal Oxide Semiconductor Field-Effect Transistor) whose gate insulating film is a silicon oxide (SiO₂) film. The field-effect transistor Qa may be of p-channel conductivity type. Alternatively, a MISFET (Metal Insulator Semiconductor FET) whose gate insulating film is a silicon nitride film or a stacked film (composite film) of a silicon nitride (Si₃N₄) film and a silicon oxide film may be used.

As shown in FIGS. 1 to 3, the field effect transistor Qa includes a channel forming portion 16 provided in the semiconductor layer 3 and a gate electrode 7 provided in the channel forming portion 16 of the semiconductor layer 3 over the upper surface portion 3a and the two side surface portions 30; and 304 of the semiconductor layer 3 with a gate insulating film 6 interposed therebetween. The field-effect transistor Qa further includes a pair of main electrode regions 15a and 15b, which are provided on the outer side of the semiconductor layer 3 and separated from each other with the channel forming portion 16 interposed therebetween in the channel length direction (gate length direction) of the channel forming portion 16. Further, the field effect transistor Qa further includes a sidewall spacer 8 provided on the sidewall of the gate electrode 7. The pair of main electrode regions 15a and 15b function as a source region and a drain region.

Here, for convenience of explanation, one main electrode region 15a of the main electrode regions 15a and 15b may be referred to as a source region 15a, and the other main electrode region 15b may be referred to as a drain region 15b. Further, the distance d₁ between the pair of main electrode regions 15a and 15b is referred to as the channel length (L) of the channel forming portion 16 (gate length (Lg) of the gate electrode 7), and the direction of this channel length is referred to as the channel length direction (gate length direction). The direction of the channel width (W) (gate width (Wg)) of the channel forming portion 16 is referred to as the channel width direction (gate width direction). In the first embodiment, as an example, since the pair of main electrode regions 15a and 15b are separated from each other in the X direction with the channel forming portion 16 interposed therebetween, the channel length direction is the X direction.

In the field effect transistor Qa, a channel (inversion layer) that electrically connects the source region (one main electrode region) 15a and the drain region (the other main electrode region) 15b by a voltage applied to the gate electrode 7 is formed (induced) in the channel forming portion 16, and a current (drain current) flows from the drain region 15b side through the channel forming portion 16 to the source region 15a side.

### <Gate Electrode, Gate Insulating Film, Sidewall Spacer>

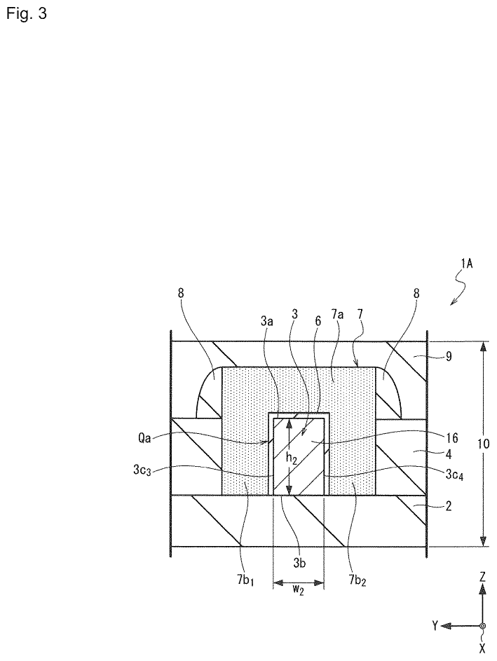

As shown in FIGS. 2 and 3, the gate electrode 7 includes, for example, but not limited to, a head portion (first portion) 7a provided on the upper surface 3a side of the semiconductor layer 3 with a gate insulating film 6 interposed therebetween and two leg portions (second portion) 7b₁ and 7b₂ that are integrated with this head portion 7a and provided on the outer side of two side surface portions 30; and 304 located on opposite sides of the semiconductor layer 3 in the Y direction with the gate insulating film 6 interposed therebetween. That is, the gate electrode 7 is provided over the upper surface portion 3a and the two side surface portions 30; and 3c₄ of the semiconductor layer 3, and has a C-shaped cross-section perpendicular to the X direction. The gate electrode 7 is made of, for example, a polycrystalline silicon film doped with impurities to reduce the resistance value.

The gate insulating film 6 is provided between the semiconductor layer 3 and the gate electrode 7 over the upper surface portion 3a and the two side surface portions 3c₃ and 3c₄ of the semiconductor layer 3. The gate insulating film 6 is made of, for example, a silicon oxide film.

The sidewall spacer 8 is provided on the sidewall of the gate electrode 7 to surround the gate electrode 7, and extends over the second insulating film 4 of the insulating layer 10 and over the semiconductor layer 3. The sidewall spacer 8 is formed in self-alignment with the gate electrode 7. This sidewall spacer 8 can be formed by, for example, forming an insulating film (spacer material) by CVD to cover the gate electrode 7, and then applying anisotropic dry etching such as RIE (Reactive Ion Etching) to this insulating film.

The sidewall spacer 8 is made of a material that has a selectivity with respect to the first to third insulating films 2, 4, and 9 included in the insulating layer 10. In the first embodiment, the sidewall spacer 8 is made of, for example, a silicon nitride film that is selective to the silicon oxide film of the insulating layer 10 and the silicon of the semiconductor layer 3. The sidewall spacer 8 ensures a distance between the gate electrode 7 and each of the pair of main electrode regions 15a and 15b.

### <Pair of Main Electrode Regions>

As shown in FIGS. 1 and 2, the pair of main electrode regions 15a and 15b include semiconductor films 13a and 13b as conductor layers that are provided on the outer side of the semiconductor layer 3 in individual contact with the side surface portions 301 and 3c₂ of the semiconductor layer 3 and are in layers different from the semiconductor layer 3. Specifically, one main electrode region 15a of the pair of main electrode regions 15a and 15b includes the semiconductor film 13a as a conductor layer that is provided on the outer side of the side surface portion 3c₁ of the semiconductor layer 3 in contact with the side surface portion 301 and is in a layer different from the semiconductor layer 3. Further, the other main electrode region 15b of the pair of main electrode regions 15a and 15b includes the semiconductor film 13b as a conductor layer that is provided on the outer side of the side surface portion 3c₂ of the semiconductor layer 3 in contact with the side surface portion 3c₂ and is in a layer different from the semiconductor layer 3. In this first embodiment, the pair of main electrode regions 15a and 15b are mainly composed of semiconductor films 13a and 13b, respectively.

The semiconductor films 13a and 13b have a different crystallinity from the semiconductor layer 3. Specifically, the semiconductor films 13a and 13b are made of, but not limited to, silicon as a semiconductor material, amorphous or polycrystal as crystallinity, and an n-type as a conductivity type. In the first embodiment, the semiconductor films 13a and 13b are made of n-type amorphous silicon doped with an n-type impurity such as arsenic (As) or phosphorus (P), for example. That is, the pair of main electrode regions 15a and 15b has a crystallinity different from that of the semiconductor layer 3 in which the channel forming portion 16 is provided. The channel forming portion 16 is provided in the semiconductor layer 3 between one main electrode region 15a and the other main electrode region 15b.

As shown in FIG. 2, the semiconductor film 13a included in one main electrode region 15a of the pair of main electrode regions 15a and 15b extends along the thickness direction (Z direction) of the insulating layer 10, and is buried in a dug portion 11a that penetrates the second insulating film 4 from the upper surface side of the third insulating film 9 of the insulating layer 10 and reaches the first insulating film 2. Furthermore, the semiconductor film 13b included in the other main electrode region 15b of the pair of main electrode regions 15a and 15b extends along the thickness direction (Z direction) of the insulating layer 10, and is buried in a dug portion 11b that penetrates the second insulating film 4 from the upper surface side of the third insulating film 9 of the insulating layer 10 and reaches the first insulating film 2.

As shown in FIG. 2, the semiconductor films 13a and 13b protrude further downward (toward the first insulating film 2 side) than the lower surface portion 3b of the semiconductor layer 3. Further, the semiconductor films 13a and 13b protrude further upward (toward the third insulating film 9 side) than the upper surface portion 3a of the semiconductor layer 3. The thickness (height) h₁ of each of the semiconductor films 13a and 13b is thicker (higher) than the thickness (height) h₂ of the semiconductor layer 3. That is, each of the semiconductor films 13a and 13b is in contact with the semiconductor layer 3 from the upper surface portion 3a side to the lower surface portion 3b side of the semiconductor layer 3. Specifically, the semiconductor films 13a and 13b are in individual contact with the side surface portions 301 and 3c₂ of the semiconductor layer 3 from the upper surface portion 3a side to the lower surface portion 3b side of the semiconductor layer 3.

As shown in FIG. 1, in each of the semiconductor films 13a and 13b, the width w₁ in the Y direction at the upper surface portion 3a of the semiconductor layer 3 is wider than the width w₂ of the semiconductor layer 3 in the Y direction. That is, the semiconductor film 13a is in contact with the entire side surface portion 3c₁ of the semiconductor layer 3 from the upper surface portion 3a side to the lower surface portion 3b side, and the semiconductor film 13b is in contact with the entire side surface portion 3c₂ of the semiconductor layer 3 from the upper surface portion 3a side to the lower surface portion 3b side. In other words, the two side surface portions 301 and 3c₂ of the semiconductor layer 3 are individually covered with the semiconductor films 13a and 13b, which are in layers different from the semiconductor layer 3.

As shown in FIG. 2, the semiconductor films 13a and 13b extend from the upper surface portion 3a side to the lower surface portion 3b side of the semiconductor layer 3. The semiconductor films 13a and 13b have an impurity concentration of 1E+17 cm⁻³ or more on the same side as the lower surface portion 3b of the semiconductor layer 3, that is, on the first insulating film 2 side.

As shown in FIG. 2, one main electrode region 15a of the pair of main electrode regions 15a and 15b is electrically and mechanically connected to a wiring 17a formed in a wiring layer on the insulating layer 10. Further, the other main electrode region 15b of the pair of main electrode regions 15a and 15b is electrically and mechanically connected to a wiring 17b formed in a wiring layer on the insulating layer 10.

As shown in FIG. 2, the dug portions 11a and 11b are formed in alignment with the sidewall spacer 8. Further, the side surface portions 301 and 3c₂ of the semiconductor layer 3 are also formed in alignment with the sidewall spacer 8. The semiconductor film 13a is formed in alignment with the sidewall spacer 8 and the side surface portion 301 of the semiconductor layer 3, and the semiconductor film 13b is formed in alignment with the sidewall spacer 8 and the side surface portion 3c₂ of the semiconductor layer 3.

That is, one main electrode region 15a of the pair of main electrode regions 15a and 15b is aligned with the sidewall spacer 8 and the side surface portion 301 of the semiconductor layer 3, in other words, it includes the semiconductor film 13a provided in the dug portion 11a along the sidewall spacer 8 and the side surface portion 3c₁ of the semiconductor layer 3. Further, the other main electrode region 15b of the pair of main electrode regions 15a and 15b is aligned with the sidewall spacer 8 and the side surface portion 301 of the semiconductor layer 3, in other words, it includes the semiconductor film 13b provided in the dug portion 11a along the sidewall spacer 8 and the side surface portion 3c₁ of the semiconductor layer 3.

Further, the boundary portion 13a₁ between the semiconductor film 13a and the semiconductor layer 3 and the boundary portion 13b₁ between the other semiconductor film 13b and the semiconductor layer 3 are also aligned with the sidewall spacer 8, in other words, it is formed along the sidewall spacer 8. That is, the boundary portions 13a₁ and 13b₁ overlap the sidewall spacer 8 in plan view. In other words, the boundary portions 13a₁ and 13b₁ overlap the outer contour of the sidewall spacer 8 in plan view.

### <<Method for Manufacturing Semiconductor Devices>>

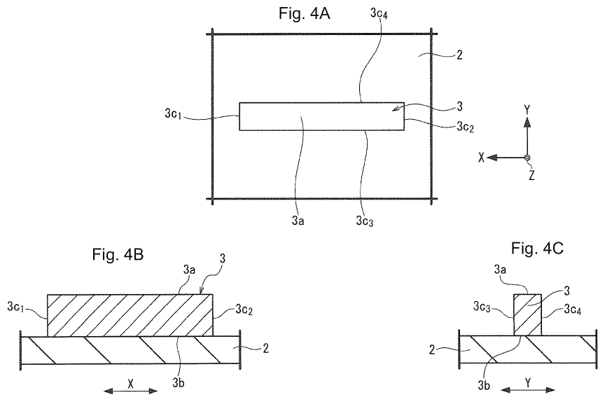

Next, a method for manufacturing the semiconductor device 1A will be described using FIGS. 4 to 12.

In FIGS. 4 to 12, (a) is a schematic plan view, (b) is a schematic vertical cross-sectional view at the same position as the cutting line a1-a1 in FIG. 1, and (c) is a schematic vertical cross-sectional view taken at the same position as the cutting line b1-b1 in FIG. 1.

In this first embodiment, a method for manufacturing a field effect transistor Qa included in the method for manufacturing a semiconductor device will be specifically explained.

First, as shown in FIGS. 4(a), 4(b), and 4(c), an island-shaped semiconductor layer 3 is formed on the first insulating film 2. The semiconductor layer 3 is formed, for example, of a rectangular parallelepiped having an upper surface portion 3a, a lower surface portion 3b, and four side surface portions 301, 3c₂, 3c₃, and 304. This semiconductor layer 3 can be formed, for example, by patterning a semiconductor substrate provided on the first insulating film 2 into a predetermined shape using a well-known thinning technique such as etching or CMP. The semiconductor layer 3 is made of, but not limited to, for example, silicon as a semiconductor material, a single crystal as a crystallinity, and an i-type (intrinsic type) as a conductivity type. The first insulating film 2 supports the semiconductor layer 3 on the lower surface portion 3b side of the semiconductor layer 3. As the first insulating film 2, for example, a silicon oxide film formed by a CVD (Chemical Vapor Deposition) method is used.

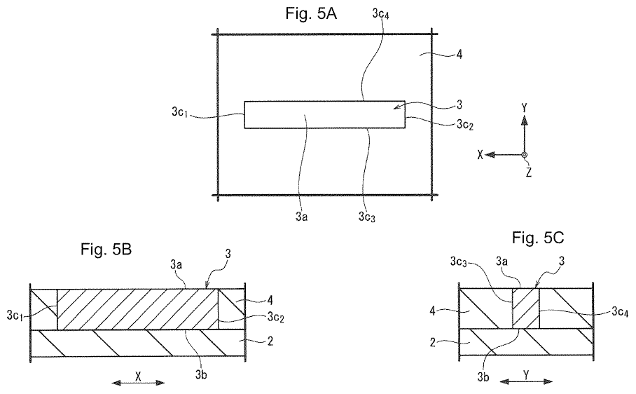

Next, as shown in FIGS. 5(a), 5(b), and 5(c), a second insulating film 4 is formed on the outer side of the semiconductor layer 3 to surround the semiconductor layer 3. The second insulating film 4 can be formed by forming, for example, a silicon oxide film on the entire surface of the first insulating film 2 including the top of the semiconductor layer 3 using a well-known film forming method (for example, a CVD method), and then selectively removing the silicon oxide film on the semiconductor layer 3 using, for example, CMP.

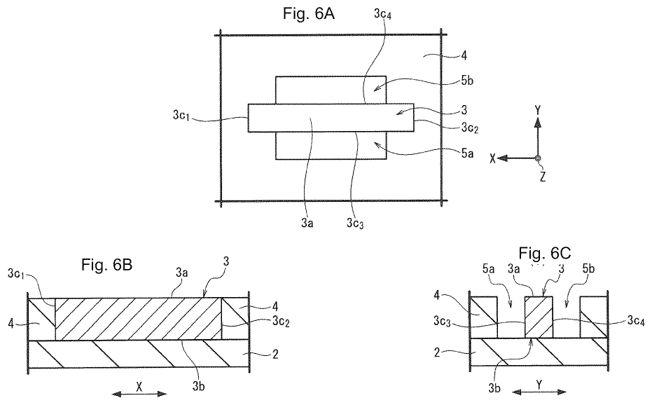

Next, as shown in FIGS. 6(a), 6(b), and 6(c), dug portions (gate electrode dug portions) 5a and 5b for exposing the side surface portions 301 and 3c₂ are formed on the outer side of the two side surface portions 301 and 3c₂ located on opposite sides of the semiconductor layer 3 in the X direction. The dug portions 5a and 5b can be formed by selectively etching the second insulating film 4 around the gate electrode 7 using, for example, well-known photolithography and dry etching techniques. The second insulating film 4 is etched under conditions that provide an etching ratio with respect to the semiconductor layer 3. The dug portions 5a and 5b are formed in a shape that the length in the X direction is shorter than the length of the semiconductor layer 3 in the X direction. Further, the dug portions 5a and 5b are formed so that the depth in the Z direction is equal to or greater than the height h₂ of the semiconductor layer 3 in the Z direction.

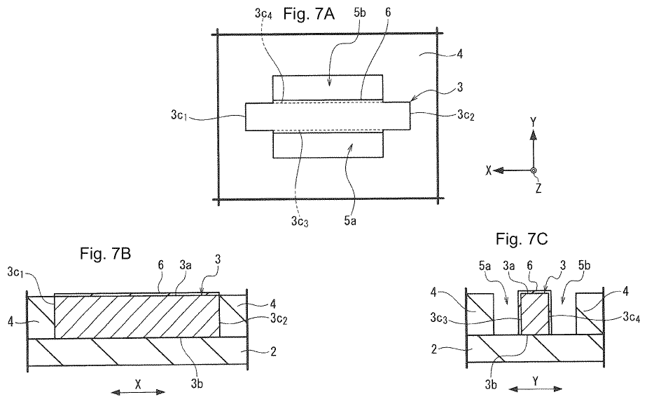

Next, as shown in FIGS. 7(a), 7(b), and 7(c), a gate insulating film 6 is formed extending over the upper surface portion 3a and the two side surface portions 3c3 and 3c₄ of the semiconductor layer 3. The gate insulating film 6 can be formed by a thermal oxidation method or a deposition method. In this first embodiment, a silicon oxide film as the gate insulating film 6 is formed by a thermal oxidation method. In this way, the gate insulating film 6 can be selectively formed in the portion of the semiconductor layer 3 exposed from the second insulating film 4.

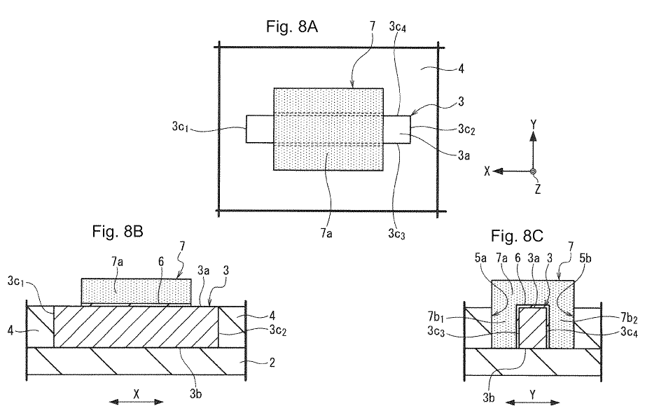

Next, as shown in FIGS. 8(a), 8(b), and 8(c), the gate electrode 7 is formed facing the upper surface portion 3a and the two side surface portions 30; and 304 of the semiconductor layer 3 with the gate insulating film 6 interposed therebetween. The gate electrode 7 includes a head portion (first portion) 7a provided on the upper surface 3a side of the semiconductor layer 3 with a gate insulating film 6 interposed therebetween and two leg portions (second portion) 7b₁ and 7b₂ that are integrated with this head portion 7a and provided on the outer side of two side surface portions 3c₃ and 3c₄ located on opposite sides of the semiconductor layer 3 in the X direction with the gate insulating film 6 interposed therebetween. The head portion 7a protrudes upward from the second insulating film 4. The two leg portions 7b₁ and 7b₂ are individually provided in the dug portions 5a and 5b, respectively.

The gate electrode 7 can be formed by forming a gate electrode film on the entire surface of the second insulating film 4 including the inside of the two dug portions 5a and 5b and the top of the semiconductor layer 3, and then patterning this gate electrode film using well-known planarization, photolithography, dry etching techniques. As the gate electrode film, for example, a polycrystalline silicon film doped with impurities to reduce the resistance value can be used. Impurities in the polycrystalline silicon film can be introduced during or after film formation. When a polycrystalline silicon film is buried inside the dug portions 5a and 5b as in the first embodiment, it is preferable to introduce impurities during film formation from the viewpoint of uniformity of impurity concentration.

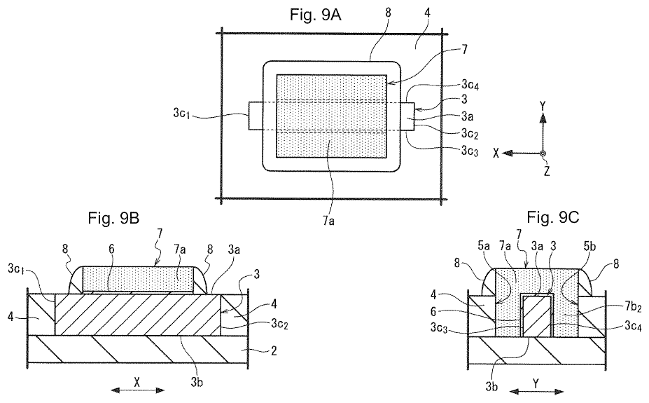

Next, as shown in FIGS. 9(a), 9(b), and 9(c), a sidewall spacer 8 is formed on the sidewalls of the head portion 7a of the gate electrode 7 that protrudes upward from the second insulating film 4. The sidewall spacer 8 can be formed by forming a silicon nitride film that is selective to a silicon oxide film, for example, as an insulating film on the entire surface of the second insulating film 4 to cover the head portion 7a of the gate electrode 7 by a CVD method and then performing anisotropic dry etching such as RIE on the silicon nitride film. The sidewall spacer 8 is formed on the sidewalls of the head portion 8a of the gate electrode 7 to surround the head portion 8a of the gate electrode 8, and is formed in self-alignment with the gate electrode 8. Further, the sidewall spacer 8 is formed on the second insulating film 4 and the semiconductor layer 3 to cross the semiconductor layer 3.

In this step, the portion of the sidewall spacer 8 on the semiconductor layer 3 is located closer to the inner side than both sides of the semiconductor layer 3 in the X direction. That is, the side surface portions 301 and 3c₂ of the semiconductor layer 3 in the X direction protrude further outward than the sidewall spacer 8.

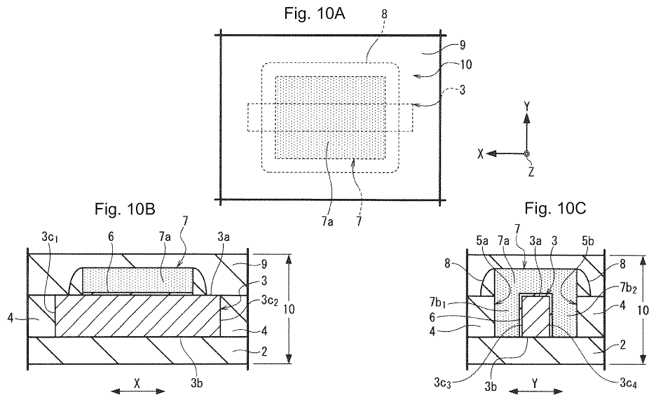

Next, as shown in FIGS. 10(a), 10(b), and 10(c), a third insulating film 9 covering the gate electrode 7 is formed on the side of the second insulating film 4 opposite to the first insulating film 2. The third insulating film 9 can be formed by forming, for example, a silicon oxide film as an insulating film on the entire surface of the second insulating film 4 including the top of the head portion 7a of the gate electrode 7, and then planarizing the surface of this silicon oxide film by CMP or the like.

In this step, an insulating layer 10 including the first insulating film 2, the second insulating film 4, and the third insulating film 9, including the semiconductor layer 3 and the gate electrode 7, and further including the sidewall spacer 8 is formed.

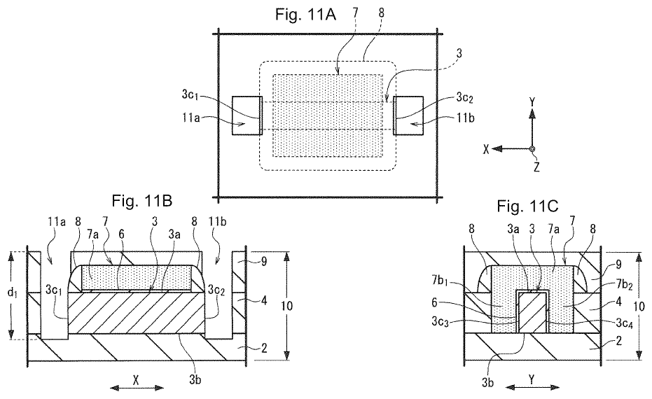

Next, as shown in FIGS. 11(a), 11(b), and 11(c), dug portions 11a and 11b reaching the first insulating film 2 from the surface of the third insulating film 9 are formed on both end sides of the semiconductor layer 3 in the X direction along (in alignment with) the sidewall spacer 8. The dug portions 11a and 11b is formed by etching the third insulating film 9 and the second insulating film 4 under etching conditions that provide an etching ratio with respect to the sidewall spacer 8 and etching both end sides of the semiconductor layer 3 protruding further outward than the sidewall spacer 8. Etching is performed using, for example, an anisotropic dry etching method.

In this step, a new side surface portion 301 is formed on one end side of the semiconductor layer 3 in the X direction along (in alignment with) the sidewall spacer 8, and a side surface portion 3c₂ is formed on the other end side along (in alignment with) the sidewall spacer 8.

The dug portions 11a and 11b are formed, for example, in a rectangular planar pattern. The dug portions 11a and 11b are formed in a width wider than the width w₁ of the semiconductor layer 3 (see FIG. 1) so that the entire surface of each of the side surface portion 301 and 302 of the semiconductor layer 3 is exposed and is formed to a depth such that the bottom portion reaches the first insulating film 2. The dug portions 11a and 11b define the width and depth of a pair of main electrode regions 15a and 15b, which will be described later.

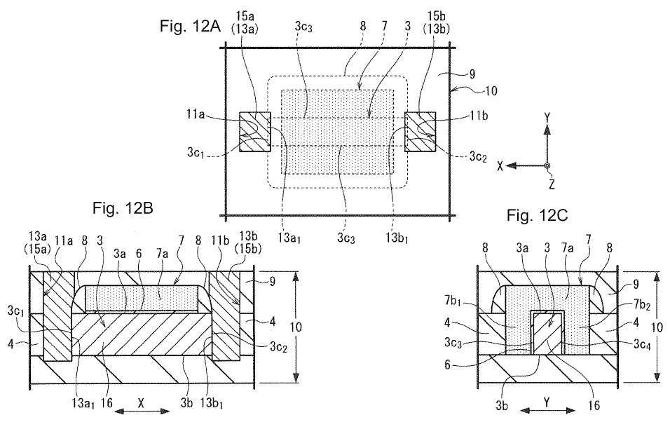

Next, as shown in FIGS. 12(a), 12(b), and 12(c), semiconductor films 13a and 13b as conductor layers are individually formed inside the two dug portions 11a and 11b, respectively. The semiconductor films 13a and 13b can be formed by forming a semiconductor film on the entire surface of the insulating layer 10 including the inside of the dug portions 11a and 11b and selectively removing the semiconductor film on the insulating layer 10 so that the semiconductor film remains individually inside the dug portions 11a and 11b.

As the semiconductor films 13a and 13b, a semiconductor film having a different crystallinity from that of the semiconductor layer 3 is used. Specifically, although not limited thereto, for example, an n-type amorphous silicon film into which an n-type impurity is introduced as an impurity to reduce the resistance value can be used.

Here, impurities in the amorphous silicon film can be introduced during or after film formation. When an amorphous silicon film is buried inside the dug portions 11a and 11b as in the first embodiment, it is preferable to introduce impurities during film formation from the viewpoint of uniformity of impurity concentration.

In this step, the semiconductor film 13a is formed along (in alignment with) the sidewall spacer 8 and the side surface portion 301 of the semiconductor layer 3, and is also formed in contact with the side surface portion 301 of the semiconductor layer 3. The semiconductor film 13a contacts the side surface portion 3c₁ on one end side of the semiconductor layer 3 from the upper surface portion 3a side to the lower surface portion 3b side of the semiconductor layer 3, and in the first embodiment, contacts the entire side surface portion 3c1.

Further, in this step, the semiconductor film 13b is formed along (in alignment with) the sidewall spacer 8 and the side surface portion 3c₂ of the semiconductor layer 3, and is also formed in contact with the side surface portion 3c₂ of the semiconductor layer 3. The semiconductor film 13b also contacts the side surface portion 3c₂ on one end side of the semiconductor layer 3 from the upper surface portion 3a side to the lower surface portion 3b side of the semiconductor layer 3, and in this first embodiment, contacts the entire side surface portion 3c2.

Through this step, one main electrode region 15a including the semiconductor film 13a is formed on the outer side of the side surface portion 301 on one end side of the semiconductor layer 3, and the other main electrode region 15b including the semiconductor film 13b is formed on the outer side of the side surface portion 3c₂ on the other end side of the semiconductor layer 3.

Further, a channel forming portion 16 is formed in the semiconductor layer 3 between the pair of main electrode regions 15a and 15b.

Further, a boundary portion 13a₁ between the semiconductor film 13a and the semiconductor layer 3 and a boundary portion 13a₂ between the semiconductor film 13b and the semiconductor layer 3 are formed individually along (in alignment with) the sidewall spacer 8.

A field-effect transistor Qa is formed, which includes the gate insulating film 6, the gate electrode 7, the sidewall spacer 8, the pair of main electrode regions 15a and 15b, and the channel forming portion 16, and which is included in the insulating layer 10.

After this, a wiring 17a electrically and mechanically connected to one main electrode region 15a and a wiring 17b electrically and mechanically connected to the other main electrode region 15b are formed in the wiring layer on the insulating layer 10, whereby the state shown in FIG. 2 is achieved.

### Main Effects of First Embodiment

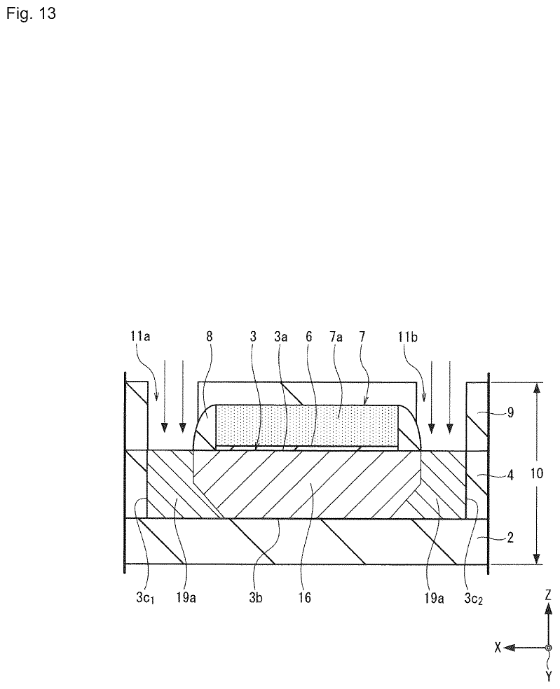

Next, the main effects of this first embodiment will be explained with reference to a comparative example shown in FIG. 13.

In a conventional field-effect transistor with an SOI-Fin structure, as explained with reference to FIG. 13, when a region that is not depleted (non-depletion region) occurs on the lower surface portion 3b side of the semiconductor layer 3 (lower part of the channel forming portion), there is a concern that a phenomenon (PD) in which the characteristics become unstable due to the accumulation of charges in the non-depletion region will occur.

Therefore, in order to prevent PD in a field-effect transistor having an SOI-Fin structure, it is preferable to form the pair of main electrode regions 19a and 19b functioning as a source region and a drain region to a depth extending from the upper surface portion 3a side to the lower surface portion 3b side of the semiconductor layer 3 (bottom surface portion side).

However, if it is attempted to form the pair of main electrode regions 19a and 19b by impurity ion implantation to a depth extending from the upper surface portion 3a side to the lower surface portion 3b side of the semiconductor layer 3, it is necessary to implant impurity ions at higher acceleration energy. As shown in FIG. 13, impurity ions enter unnecessary regions due to lateral diffusion with respect to the direction of impurity ion implantation. Therefore, the lateral extension of the pair of main electrode regions 19a and 19b differs between the upper surface portion 3a side and the lower surface portion 3b side of the semiconductor layer 3, resulting in a short effective channel length (gate length: Lg). As a result, a short-channel effect is more likely to occur. In a field-effect transistor with an SOI-Fin structure, by increasing the thickness of the semiconductor layer 3, the effective gate width can be increased and the driving capability can be increased. However, the difference in lateral extension of the pair of main electrode regions 19a and 19b becomes more noticeable as the thickness of the semiconductor layer 3 increases.

On the other hand, as shown in FIGS. 1 to 3, in the field-effect transistor Qa of the first embodiment, the pair of main electrode regions 15a and 15b functioning as the source region and the drain region individually include the semiconductor films 13a and 13b which are provided on the outer side of the two side surface portions 301 and 3c₂ in the X direction of the semiconductor layer 3 in contact with the semiconductor layer 3, and which are in layers different from the semiconductor layer 3. The semiconductor film 13a is in contact with the entire side surface portion 301 of the semiconductor layer 3, and the semiconductor film 13b is in contact with the entire side surface portion 3c₂ of the semiconductor layer 3. Therefore, without using impurity ion implantation, it is possible to provide the pair of main electrode regions 15a and 15b on the outer side of the two side surface portions 301 and 3c₂ of the semiconductor layer 3 in contact with the semiconductor layer 3 from the upper surface portion 3a side to the lower surface portion 3b side of the semiconductor layer 3. In this way, the channel forming portion 16 of the semiconductor layer 3 sandwiched between the pair of main electrode regions 15a and 15b can be used as an active region from the upper surface portion 3a side to the lower surface portion 3b side of the semiconductor layer 3, and partial depletion in the channel forming portion 16 can be suppressed. In other words, the channel forming portion 16 can be completely depleted.

Without using impurity ion implantation, it is possible to provide the pair of main electrode regions 15a and 15b individually including the semiconductor film 13a that is in contact with the entire side surface portion 301 of the semiconductor layer 3 from the upper surface portion 3a side to the lower surface portion 3b side of the semiconductor layer 3 and the semiconductor film 13b that is in contact with the entire side surface portion 3c₂ of the semiconductor layer 3 from the upper surface portion 3a side to the lower surface portion 3b side of the semiconductor layer 3. Thus, as explained in the comparative example of FIG. 13, it is possible to avoid a short-channel effect caused by impurity ion implantation.

Therefore, according to the semiconductor device 1A according to the first embodiment, the channel forming portion 16 can be completely depleted, and the occurrence of the short-channel effect can be suppressed.

Further, the sidewall spacer 8 is formed on the sidewall of the head portion 7a of the gate electrode 7 in alignment with the head portion 7a of the gate electrode 7. The boundary portions 13a₁ and 13b₁ between the semiconductor layer 3 and the semiconductor films 13a and 13b are formed in alignment with the sidewall spacer 8. Therefore, according to the semiconductor device 1A of the first embodiment, variations in the channel length di can be suppressed, and a highly reliable field effect transistor Qa can be provided.

Note that the semiconductor films 13a and 13b do not necessarily need to be in contact with the entire surfaces of the side surface portions 13c₁ and 13c₂ of the semiconductor layer 3. In short, the semiconductor films 13a and 13b only need to be in contact with the side surface portions 1301 and 13c₂ of the semiconductor layer 3. The semiconductor films 13a and 13b are preferably in contact with the side surface portions 301 and 3c₂ from the upper surface portion 3a side to the lower surface portion 3b side of the semiconductor layer 3. Furthermore, it is more preferable that the semiconductor films 13a and 13b are in contact with the entire surfaces of the side surface portions 301 and 3c₂ from the upper surface portion 3a side to the lower surface portion 3b side of the semiconductor layer 3. Further, in the first embodiment described above, the semiconductor films 13a and 13b are used as the conductor layers, but the conductor films may be metal films such as aluminum (Al) or copper (Cu), or alloy films mainly composed of these elements. Alternatively, a high melting point metal film such as titanium (Ti) or tungsten (W) can be used.

### Second Embodiment

A semiconductor device 1B according to the second embodiment of the present technology basically has the same configuration as the semiconductor device 1A of the first embodiment described above and differs in the following configuration.

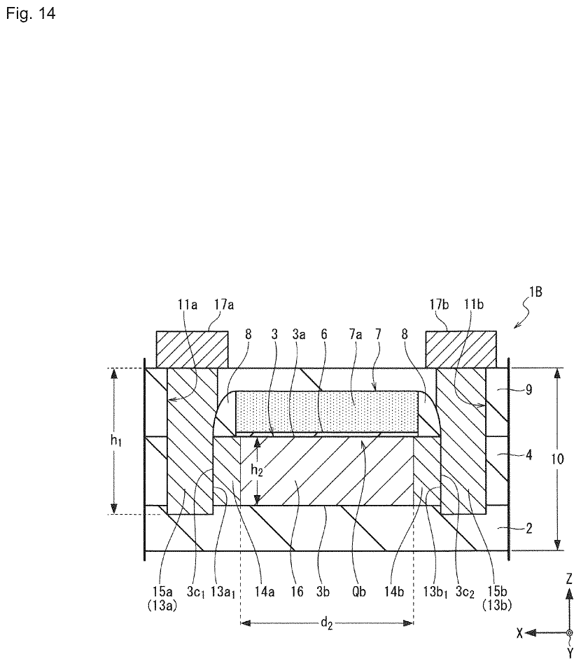

That is, as shown in FIG. 14, a semiconductor device 1B according to the second embodiment of the present technology includes a field effect transistor Qb in place of the field effect transistor Qa shown in FIG. 2 of the first embodiment described above. In addition to the configuration of the field-effect transistor Qa, the field effect transistor Qb further includes a pair of extension regions 14a and 14b. The other configurations are the same as those in the above-described first embodiment.

As shown in FIG. 14, the pair of extension regions 14a and 14b are provided on both end sides (the side surface portion 301 side and the side surface portion 3c2 side) in the X direction of the semiconductor layer 3 in individual contact with the semiconductor films 13a and 13b as conductor layers, respectively. Specifically, one extension region 14a of the pair of extension regions 14a and 14b is provided on the side surface portion 3c₁ side of the semiconductor layer 3 in contact with the semiconductor film 13a. Further, the other extension region 14b of the pair of extension regions 14a and 14b is provided on the side surface portion 3c₂ side of the semiconductor layer 3 in contact with the semiconductor film 13b.

The extension regions 14a and 14b are semiconductor regions containing impurities that are individually diffused into the semiconductor layer 3 from the respective semiconductor films 13a and 13b. In the first embodiment, since the semiconductor films 13a and 13b are made of an n-type semiconductor, the extension regions 14a and 14b are also made of an n-type semiconductor region.

The impurity concentration of the pair of extension regions 14a and 14b is higher than the impurity concentration of the semiconductor layer 3 (the impurity concentration of the channel forming portion 16) and lower than the impurity concentration of the semiconductor films 13a and 13b.

Here, as shown in FIG. 14, in the field effect transistor Qb of the second embodiment, the distance de between the pair of extension regions 14a and 14b is the channel length (gate length) of the channel forming portion 16. In the second embodiment, as an example, since the pair of extension regions 14a and 14b are separated from each other in the X direction with the channel forming portion 16 interposed therebetween, the channel length direction is the X direction.

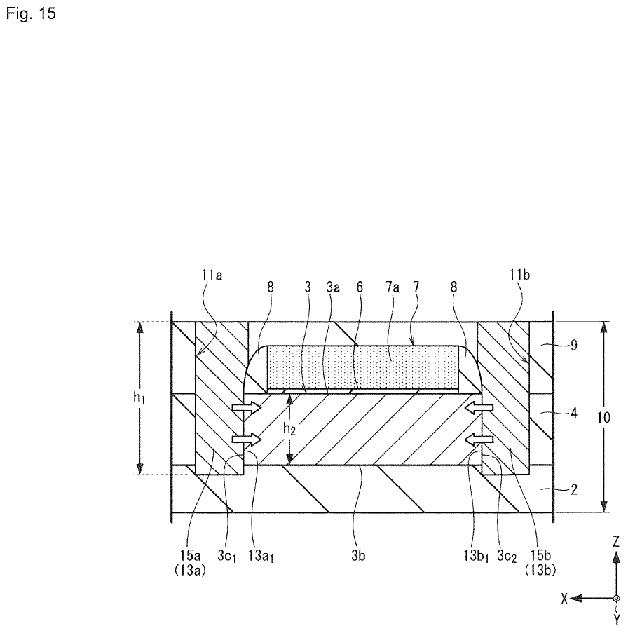

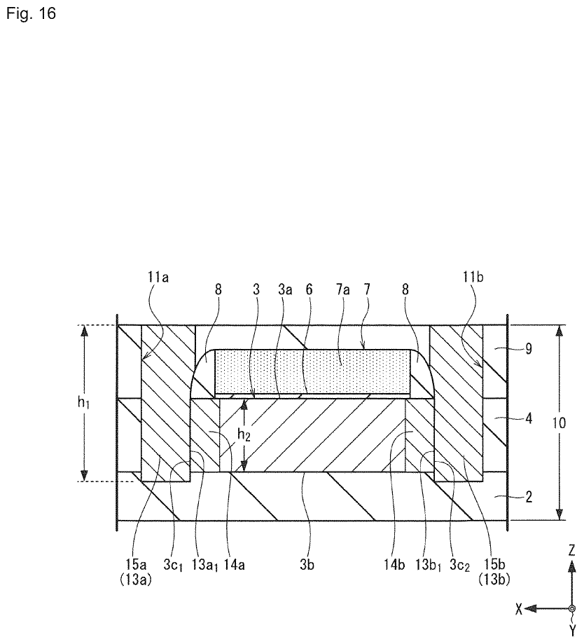

As shown in FIG. 15, the pair of extension regions 14a and 14b are formed by forming the semiconductor films 13a and 13b in the dug portions 11a and 11b, and then performing heat treatment so that impurities of the semiconductor films 13a and 13b are diffused toward the side surface portion 301 side and the side surface portion 302 side of the semiconductor layer 3. In this way, as shown in FIG. 16, the extension regions 14a and 14b are individually formed on the side surface portion 301 side and the side surface portion 3c₂ side of the semiconductor layer 3.

In this step, since the semiconductor film 13a is provided from the upper surface portion 3a side to the lower surface portion 3b side of the semiconductor layer 3, the extension region 14a is also provided from the upper surface portion 3a side to the lower surface portion 3b side of the semiconductor layer 3. The extension region 14a is formed so that the width (thickness) inward from the side surface portion 3c₁ side of the semiconductor layer 3 is substantially constant from the upper surface portion 3a side to the lower surface portion 3b side of the semiconductor layer 3. Similarly, since the semiconductor film 13b is provided from the upper surface portion 3a side to the lower surface portion 3b side of the semiconductor layer 3, the extension region 14b is also formed from the upper surface portion 3a side to the lower surface portion 3b side of the semiconductor layer 3. The extension region 14a is formed so that the width (thickness) inward from the side surface portion 301 side of the semiconductor layer 3 is substantially constant from the upper surface portion 3a side to the lower surface portion 3b side of the semiconductor layer 3.

According to the semiconductor device 1B according to the second embodiment, the same effects as those of the semiconductor device 1A according to the first embodiment described above are obtained.

Furthermore, by providing the extension regions 14a and 14b, noise due to interface defects between the semiconductor layers 3 and the semiconductor films 13a and 13b can be avoided.

Note that in the second embodiment described above, the pair of extension regions 14a and 14b are not included in the constituent elements of the pair of main electrode regions 15a and 15b, but the pair of main electrode regions 15a and 15b may be defined as including the pair of extension regions 14a and 14b. In this case, as an example, the pair of main electrode regions 15a and 15b are configured to include the pair of semiconductor films 13a and 13b and the pair of extension regions 14a and 14b, respectively.

### Modified Example of Second Embodiment

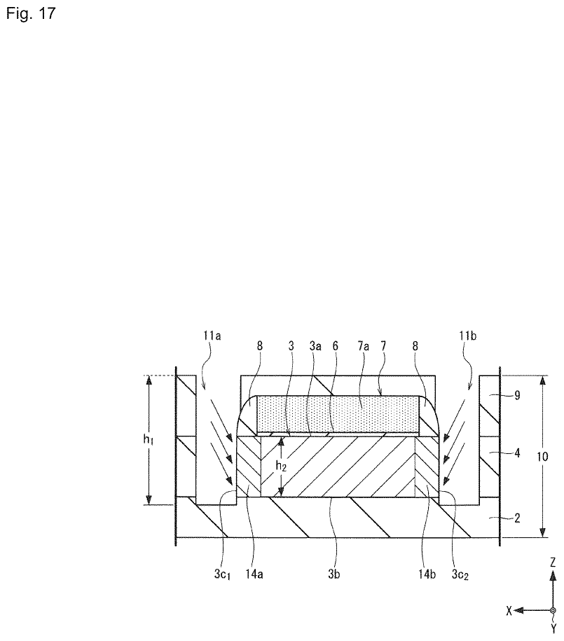

In the second embodiment described above, a case has been described in which the extension regions 14a and 14b are formed by thermal diffusion, but the extension regions 14a and 14b may be formed by impurity ion implantation. Specifically, as shown in FIG. 17, after the dug portions 11a and 11b are formed in the insulating layer 10, impurity ions are implanted into the side surface portion 3c₁ side of the semiconductor layer 3 through the dug portion 11a to form the extension region 14a, and impurity ions are implanted into the side surface portion 3c₂ side of the semiconductor layer 3 through the dug portion 11b to form the extension region 14b. The impurity ions are implanted in a state where the implantation direction is inclined with respect to the side surface portions 3c1 and 3c₂ of the semiconductor layer 3.

In the semiconductor device according to this modified example of the second embodiment, the same effects as the semiconductor device 1B according to the above-described second embodiment are obtained.

### Third Embodiment

A semiconductor device 1C according to the third embodiment of the present technology basically has the same configuration as the semiconductor device 1B according to the second embodiment described above and differs in the following configuration.

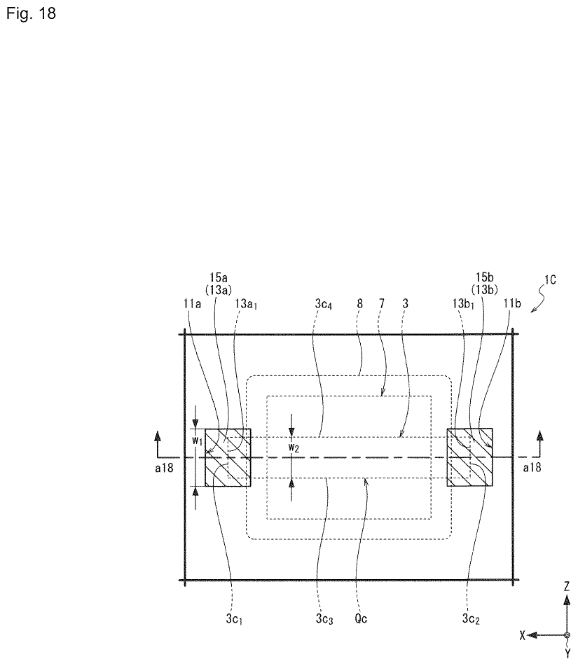

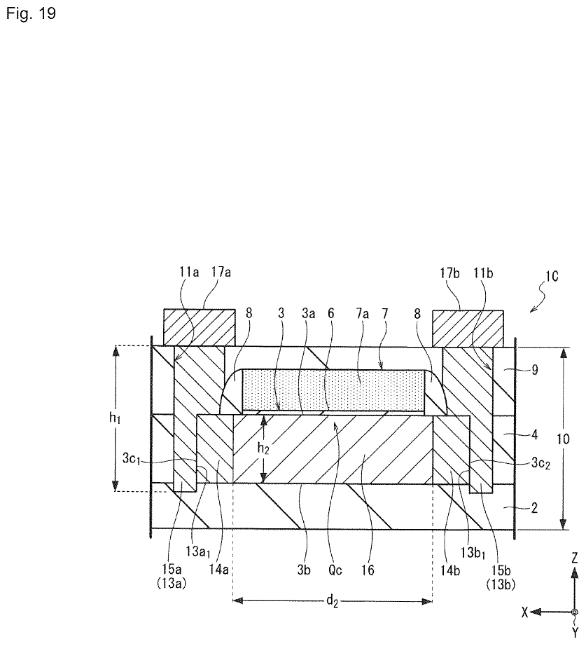

That is, as shown in FIGS. 18 and 19, a semiconductor device 1C according to the third embodiment of the present technology includes a field effect transistor Qc in place of the field effect transistor Qb shown in FIG. 14 of the second embodiment described above. The field effect transistor Qc has basically the same configuration as the field effect transistor Qb, but the positions of the boundary portions 13a₁ and 13b₁ between the semiconductor layer 3 and the semiconductor films 13a and 13b are different.

Specifically, in the field effect transistor Qb of the second embodiment described above, as shown in FIG. 14, as in the first embodiment described above, the boundary portions 13a₁ and 13b₁ between the semiconductor layer 3 and the semiconductor films 13a and 13b are provided at positions overlapping the sidewall spacer 8 in plan view.

On the other hand, in the field effect transistor Qc of the third embodiment, as shown in FIGS. 18 and 19, the boundary portions 13a₁ and 13b₁ between the semiconductor layer 3 and the semiconductor films 13a and 13b are located outside the sidewall spacer 8 in plan view.

The configuration in which the boundary portions 13a₁ and 13b₁ are located outside the sidewall spacer 8 is achieved by etching the insulating layer 10 under conditions that provide an etching ratio with respect to the sidewall spacer 8 and the semiconductor layer 3 to form the dug portions 11a and 11b in the manufacturing process of the semiconductor device 1C.

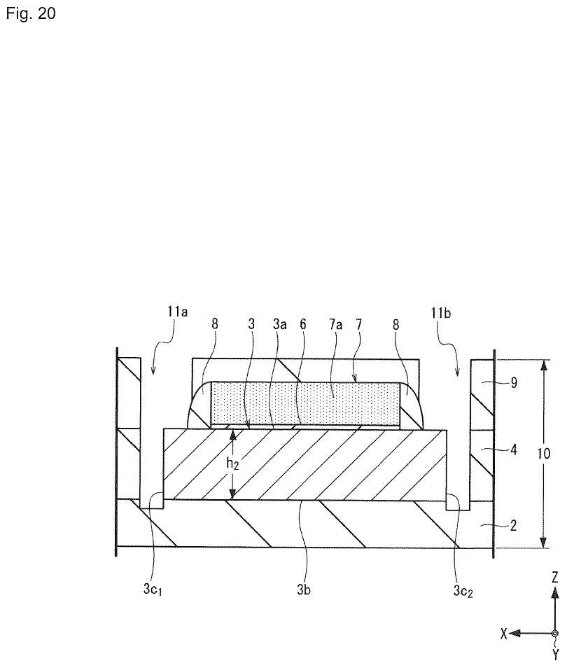

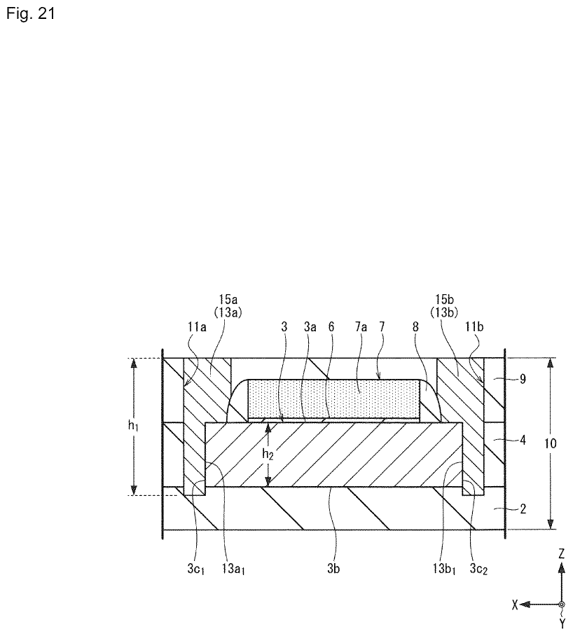

Specifically, as shown in FIG. 20, a sidewall spacer 8 is formed closer to the inner side than the side surface portions 3a₁ and 3a₂ of the semiconductor layer 3. As shown in FIG. 20, the insulating layer 10 is selectively etched under conditions that provide an etching ratio with respect to the semiconductor layer 3 and the sidewall spacer 8 to form the dug portions 11a and 11b so that portions of the semiconductor layer 3 on the sides of the side surface portions 301 and 3c₂ remain in the dug portions. Thereafter, the same steps as in the first embodiment described above are performed to selectively form semiconductor films 13a and 13b in the dug portions 11a and 11b, as shown in FIG. 21, whereby a configuration can be obtained in which the boundary portions 13a₁ and 13b₂ between the semiconductor layer 3 and the semiconductor films 13a and 13b are located outside the sidewall spacer 8. After that, heat treatment is performed to diffuse impurities of the semiconductor films 13a and 13b into the side surface portion 3c₁ side and the side surface portion 3c₂ of the semiconductor layer 3, whereby the extension regions 14a and 14b can be individually formed on the side surface portion 3c₁ side and the side surface portion 3c₂ side of the semiconductor layer 3 as shown in FIG. 19.

The semiconductor device 1C according to the third embodiment also provides the same effects as the semiconductor device 1B according to the second embodiment described above.

Further, according to the semiconductor device 1C according to the third embodiment, the separation distance between the gate electrode 7 and the boundary portions (13a₁ and 13b1) between the semiconductor layer 3 and the semiconductor films 13a and 13b can be increased, and thus, noise can be reduced.

Furthermore, by providing the pair of extension regions 14a and 14b, the resistance value (channel resistance value) between the source region 15a (one main electrode region 15a) and the drain region 15b (the other main electrode region 15b) can be reduced.

### Fourth Embodiment

A semiconductor device 1D according to the fourth embodiment of the present technology basically has the same configuration as the semiconductor device 1A of the first embodiment described above and differs in the following configuration.

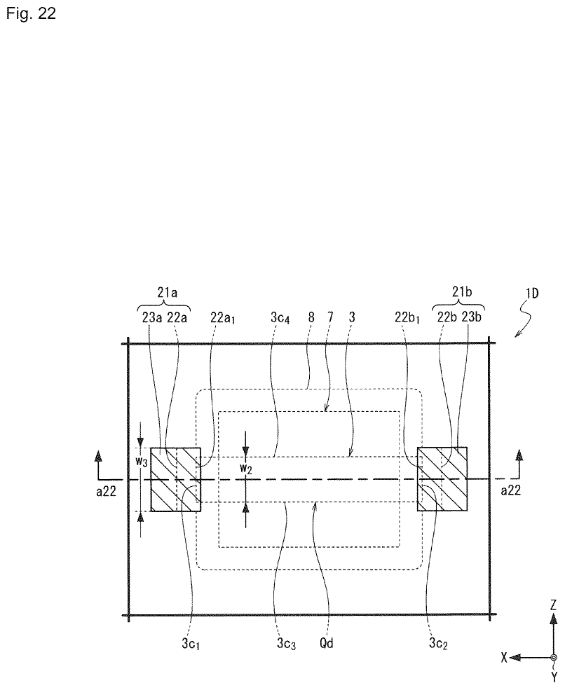

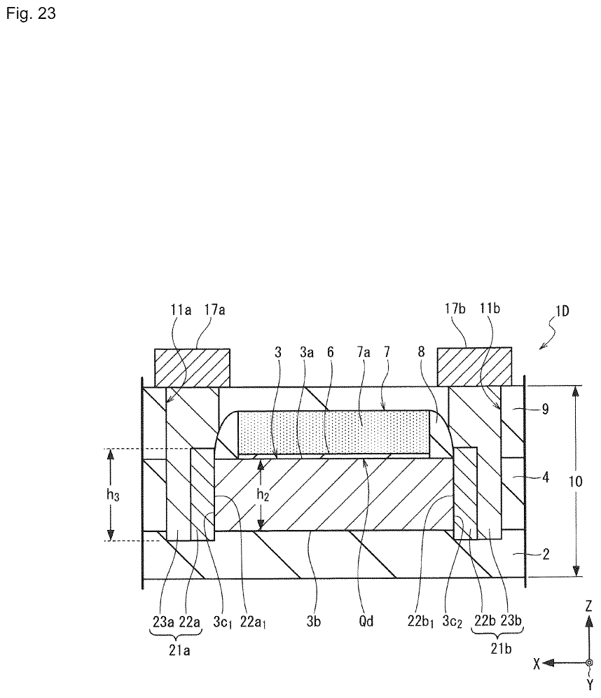

That is, as shown in FIGS. 22 and 23, the semiconductor device 1D according to the fourth embodiment of the present technology includes a field-effect transistor Qd in place of the field effect transistor Qa shown in FIG. 2 of the first embodiment described above. The field effect transistor Qd includes a pair of main electrode regions 21a and 21b in place of the pair of main electrode regions 15a and 15b of the field-effect transistor Qa. The other configurations are similar to those in the first embodiment described above.

As shown in FIGS. 22 and 23, the pair of main electrode regions 21a and 21b are configured to individually include epitaxial layers 22a and 22b as conductor layers and conductive filling layers 23a and 23b, respectively.

<Epitaxial layer>

As shown in FIG. 23, the epitaxial layer 22a included in one main electrode region 21a of the pair of main electrode regions 21a and 21b is provided in contact with the semiconductor layer 3 on the outer side of the side surface portion 301 of the semiconductor layer 3 and is configured with a layer different from the semiconductor layer 3. The epitaxial layer 22a is provided in the dug portion 11a of the insulating layer 10.

The epitaxial layer 22b included in the other main electrode region 21b of the pair of main electrode regions 21a and 21b is provided in contact with the semiconductor layer 3 on the outer side of the side surface portion 3c₂ of the semiconductor layer 3, and is configured with a layer different from the semiconductor layer 3. The epitaxial layer 22b is provided in the dug portion 11b.

The epitaxial layers 22a and 22b are layers formed on the semiconductor layer 3 by epitaxial growth. In epitaxial growth, an n-type, p-type, or i-type single crystal layer can be formed by inheriting the crystallinity of the semiconductor layer 3 as a base layer (lower layer). Therefore, the epitaxial layers 22a and 22b are covalently bonded to the semiconductor layer 3. In the fourth embodiment, the epitaxial layer is formed of, but not limited to, an n-type single-crystal silicon layer into which, for example, arsenic (As) or phosphorus (P) is introduced as an n-type impurity.

As shown in FIG. 23, the epitaxial layers 22a and 22b protrude further downward (toward the first insulating film 2 side) than the lower surface portion 3b of the semiconductor layer 3. Further, the epitaxial layers 22a and 22b protrude further upward (toward the third insulating film 9 side) than the upper surface portion 3a of the semiconductor layer 3. The thickness (height) h₃ of the epitaxial layers 22a and 22b is thicker (higher) than the thickness (height) h₂ of the semiconductor layer 3. That is, the epitaxial layers 22a and 22b are in contact with the semiconductor layer 3 from the upper surface portion 3a side to the lower surface portion 3b side of the semiconductor layer 3. Specifically, the semiconductor films 13a and 13b are in individual contact with the side surface portions 301 and 3c₂ of the semiconductor layer 3 from the upper surface portion 3a side to the lower surface portion 3b side of the semiconductor layer 3.

As shown in FIG. 22, in the epitaxial layers 22a and 22b, the width w₃ in the Y direction at the upper surface portion 3a of the semiconductor layer 3 is wider than the width w₂ of the semiconductor layer 3 in the Y direction. That is, the epitaxial layer 22a contacts the entire side surface portion 301 from the upper surface portion 3a side to the lower surface portion 3b side of the semiconductor layer 3, and the epitaxial layer 22b contacts the entire side surface portion 3c2 from the upper surface portion 3a side to the lower surface portion 3b side of the semiconductor layer 3. In other words, the two side surface portions 301 and 3c2 of the semiconductor layer 3 are individually covered with the epitaxial layers 22a and 22b, which are in layers different from the semiconductor layer 3.

As shown in FIG. 23, the epitaxial layers 22a and 22b extend from the upper surface portion 3a to the lower surface portion 3b of the semiconductor layer 3. In the epitaxial layers 22a and 22b, the impurity concentration on the same side as the lower surface portion 3b of the semiconductor layer 3, that is, on the first insulating film 2 side, is 1E+17 cm⁻³ or more.

### <Filling Layer>

As shown in FIG. 23, the filling layer 23a included in one main electrode region 21a of the pair of main electrode regions 21a and 21b is provided in contact with the epitaxial layer 22a on the outer side of the side surface portion 301 of the semiconductor layer 3 and is electrically connected to the epitaxial layer 22a. The filling layer 23a is provided in the dug portion 11a of the insulating layer 10 together with the epitaxial layer 22a.

As shown in FIG. 23, the filling layer 23b included in the other main electrode region 21b of the pair of main electrode regions 21a and 21b is provided in contact with the epitaxial layer 22b on the outer side of the side surface portion 3c₂ of the semiconductor layer 3, and is electrically connected to the epitaxial layer 22b. The filling layer 23b is provided in the dug portion 11b of the insulating layer 10 together with the epitaxial layer 22b.

As shown in FIG. 23, the filling layers 23a and 23b protrude further downward (toward the first insulating film 2) than the lower surface portion 3b of the semiconductor layer 3. Further, the filling layers 23a and 23b protrude further upward (toward the third insulating film 9 side) than the upper surface portion 3a of the semiconductor layer 3. The thickness (height) of the filling layers 23a and 23b in the Z direction is thicker (higher) than the thickness (height) h₃ of the epitaxial layers 22a and 22b in the Z direction. That is, the filling layer 23a is in contact with the epitaxial layer 22a from the upper surface portion 3a side to the lower surface portion 3b side of the epitaxial layer 22a, and the filling layer 23b is in contact with the epitaxial layer 22b from the upper surface portion side to the lower surface portion side of the epitaxial layer 22b.

As shown in FIG. 23, the width in the Y direction of the filling layers 23a and 23b is equal to the width w₃ of the epitaxial layers 22a and 22b. That is, the filling layer 23a contacts the entire side surface portion of the epitaxial layer 22a from the upper surface portion side to the lower surface portion side of the epitaxial layer 22a, and the filling layer 23b contacts the entire side surface portion of the epitaxial layer 22b from the upper surface portion side to the lower surface portion side of the epitaxial layer 22b.

Although not limited thereto, the filling layers 23a and 23b may be, for example, metal films such as aluminum (Al) or copper (Cu), or alloy films mainly composed of these elements. Alternatively, a high melting point metal film such as titanium (Ti) or tungsten (W) can be used.

As shown in FIG. 23, one main electrode region 21a of the pair of main electrode regions 21a and 21b is electrically and mechanically connected to a wiring 17a formed in a wiring layer on the insulating layer 10. Further, the other main electrode region 21b of the pair of main electrode regions 21a and 21b is electrically and mechanically connected to a wiring 17b formed in a wiring layer on the insulating layer 10.

The pair of main electrode regions 21a and 21b is achieved by epitaxially growing an epitaxial layer on the semiconductor layer 3 through the dug portions 11a and 11b of the insulating layer 10 in a semiconductor device manufacturing process.

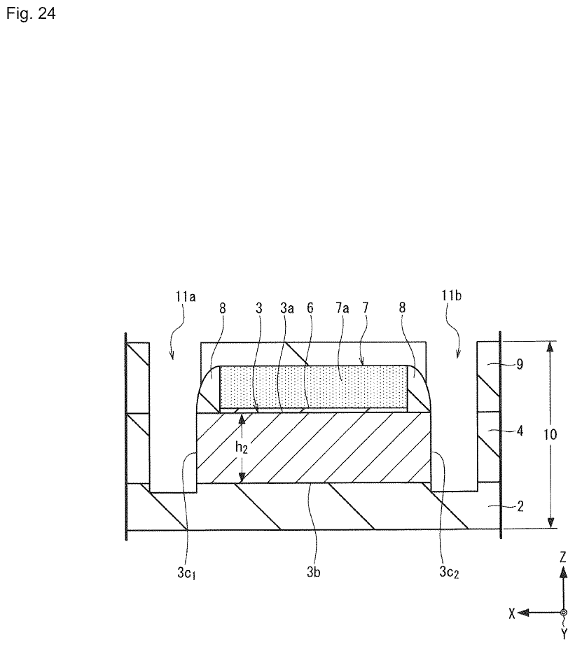

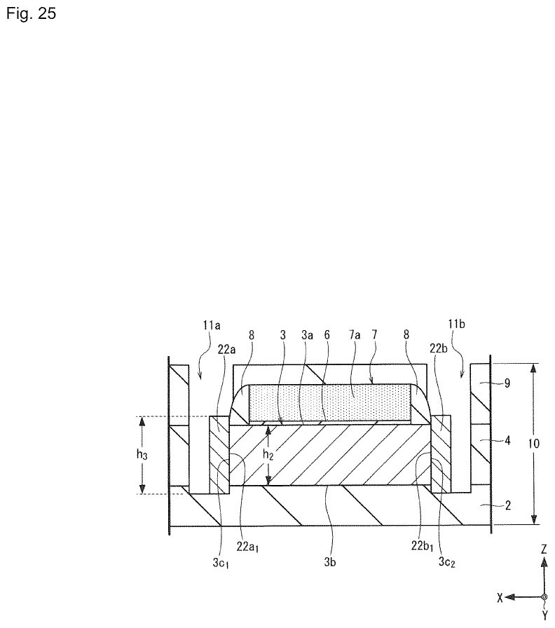

Specifically, as shown in FIG. 24, the dug portions 11a and 11b are formed in the insulating layer 10 by the same steps as in the first embodiment described above. As shown in FIG. 25, the epitaxial layer 22a is epitaxially grown on the side surface portion 301 of the semiconductor layer 3 through the dug portion 11a, and the epitaxial layer 22b is epitaxially grown on the side surface portion 302 of the semiconductor layer 3 through the dug portion 11b. Thereafter, by individually forming the conductive filling layers 23a and 23b in the dug portions 11a and 11b, as shown in FIG. 23, the main electrode region 21a including the epitaxial layer 22a and the filling layer 23a and the main electrode region 21b including the epitaxial layer 22b and the filling layer 23b can be formed.

In the semiconductor device 1D according to the fourth embodiment, the same effects as in the semiconductor device 1A according to the above-described first embodiment are obtained.

Further, since the epitaxial layers 22a and 22b have better carrier mobility than polycrystalline or amorphous semiconductor films, the parasitic resistance of the field-effect transistor Qd can be reduced and the speed can be increased as compared to the field effect transistor Qa of the first embodiment described above.

### Fifth Embodiment

A semiconductor device 1E according to the fifth embodiment of the present technology basically has the same configuration as the semiconductor device 1A of the first embodiment described above and differs in the following configuration.

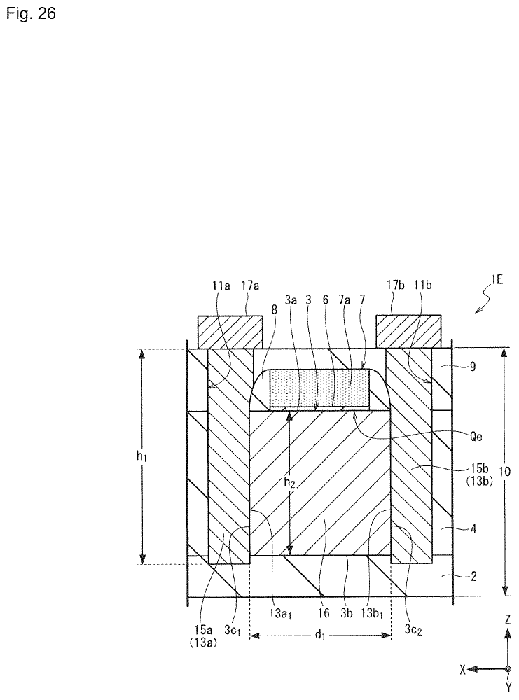

That is, as shown in FIG. 26, in the semiconductor device 1E according to the fifth embodiment of the present technology, the thickness t₂ of the semiconductor layer 3 is thicker than the distance d₁ (channel length) between the pair of main electrode regions 15a and 15b. The semiconductor device 1E according to the fifth embodiment of the present technology includes a field effect transistor Qe in place of the field effect transistor Qa of the first embodiment described above. The field-effect transistor Qe basically has the same configuration as the field-effect transistor Qa, and the thickness of the channel forming portion 16 is thicker than the channel length.

In the field effect transistor Qe of the fifth embodiment, similarly to the field-effect transistor Qa described above, the pair of main electrode regions 15a and 15b functioning as a source region and a drain region individually include the semiconductor films 13a and 13b which are provided in contact with the semiconductor layer 3 on the outer side of the two side surface portions 301 and 3c₂ in the X direction of the semiconductor layer 3 and are in layers different from the semiconductor layer 3. The semiconductor film 13a contacts the entire side surface portion 301 from the upper surface portion 3a side to the lower surface portion 3b side of the semiconductor layer 3, and the semiconductor film 13b contacts the entire side surface portion 3c₂ from the upper surface portion 3a side to the lower surface portion 3b side of the semiconductor layer 3.

Therefore, in the semiconductor device 1E according to the fifth embodiment as well, the channel forming portion 16 can be completely depleted and the occurrence of the short-channel effect can be prevented, similarly to the semiconductor device 1A according to the first embodiment described above.

### Sixth Embodiment

A semiconductor device 1F according to the sixth embodiment of the present technology basically has the same configuration as the semiconductor device 1B according to the second embodiment described above and differs in the following configuration.

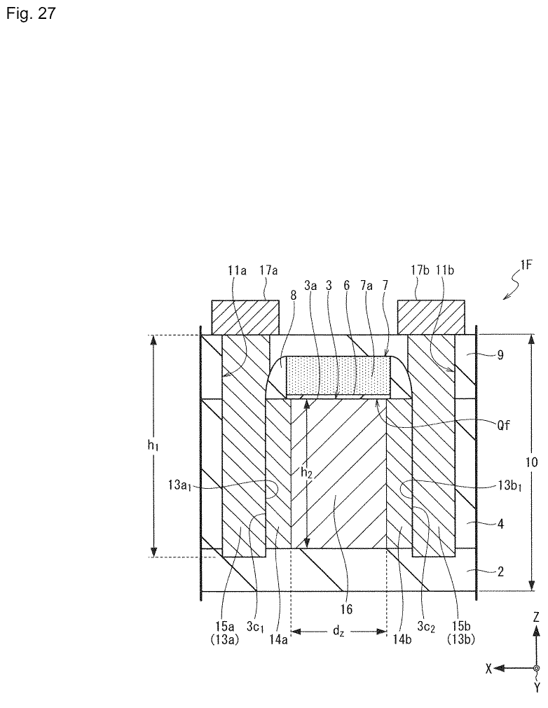

That is, as shown in FIG. 27, in the semiconductor device 1F according to the sixth embodiment of the present technology, the thickness t₂ of the semiconductor layer 3 is thicker than the distance de (channel length) between the pair of extension regions 14a and 14b. The semiconductor device 1F according to the fifth embodiment of the present technology includes a field-effect transistor Qf instead of the field effect transistor Qb of the second embodiment described above. The field-effect transistor Qf basically has the same configuration as the field-effect transistor Qb, and the thickness of the channel forming portion 16 is thicker than the channel length.

Therefore, in the semiconductor device 1F according to the fifth embodiment, the same effects as in the semiconductor device 1B according to the second embodiment described above are obtained.

### Seventh Embodiment

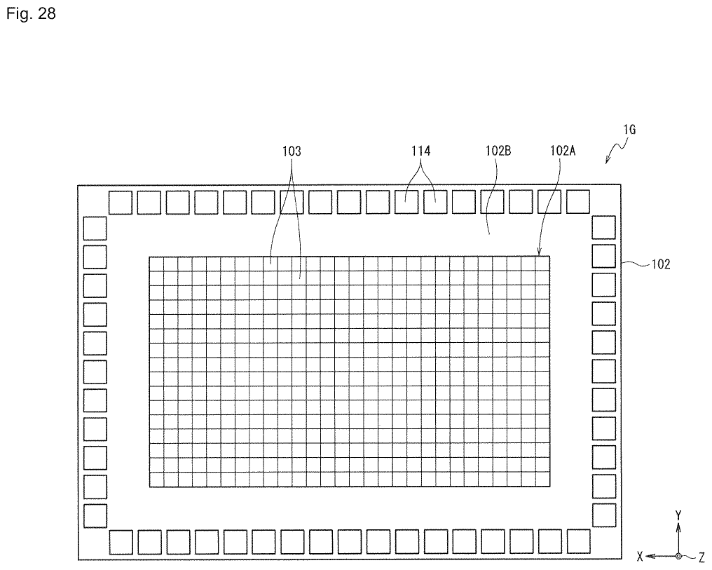

In the seventh embodiment, an example in which the present technology is applied to a solid-state imaging device, which is a back-illuminated CMOS (Complementary Metal Oxide Semiconductor) image sensor included in a light detection device as a semiconductor device will be described using FIGS. 28 to 31.

### <<Overall Configuration of Solid-State Imaging Device>>

First, the overall configuration of a solid-state imaging device 1G will be described.

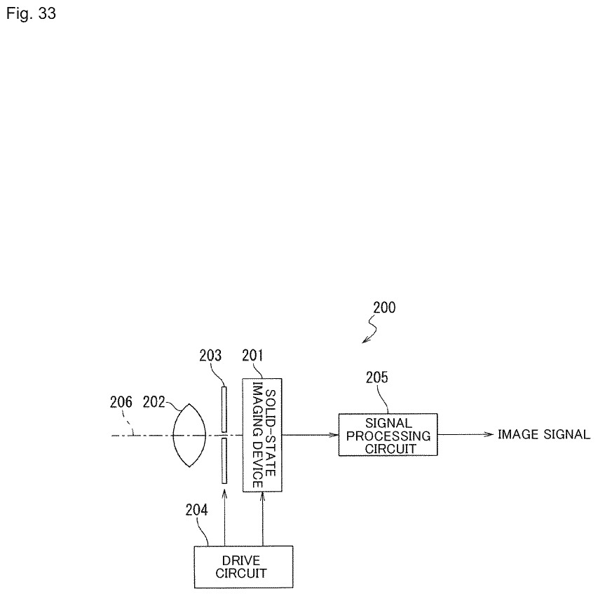

As shown in FIG. 28, the solid-state imaging device 1G according to the seventh embodiment of the present technology is mainly configured with a semiconductor chip 102 having a rectangular two-dimensional planar shape in plan view. That is, the solid-state imaging device 1G is mounted on the semiconductor chip 102, and the semiconductor chip 102 can be regarded as the solid-state imaging device 1G. As shown in FIG. 33, this solid-state imaging device 1G (201) captures image light (incident light 206) from a subject through an optical lens 202, converts the amount of the incident light 206 formed on an imaging surface into an electrical signal for each pixel, and output the electrical signal as a pixel signal.

As shown in FIG. 28, the semiconductor chip 102 on which the solid-state imaging device 1G is mounted has a rectangular pixel array portion 102A provided at the center in a two-dimensional plane including the X direction and the Y direction that are orthogonal to each other and a peripheral portion 102B provided outside the pixel array portion 102A to surround the pixel array portion 102A.

The pixel array portion 102A is a light-receiving surface that receives light collected by the optical lens (optical system) 202 shown in FIG. 33, for example. A plurality of pixels 103 are arranged in the pixel array portion 102A in a matrix in a two-dimensional plane including the X direction and the Y direction. In other words, the pixels 103 are repeatedly arranged in the X direction and the Y direction, which are orthogonal to each other within a two-dimensional plane.

As shown in FIG. 28, a plurality of bonding pads 114 are arranged in the peripheral portion 102B. The plurality of bonding pads 114, for example, are arranged along each side among the four sides in the two-dimensional plane of the semiconductor chip 102. The plurality of bonding pads 114 functions as an input/output terminal that electrically connects the semiconductor chip 102 and an external device.

### <Logic Circuit>

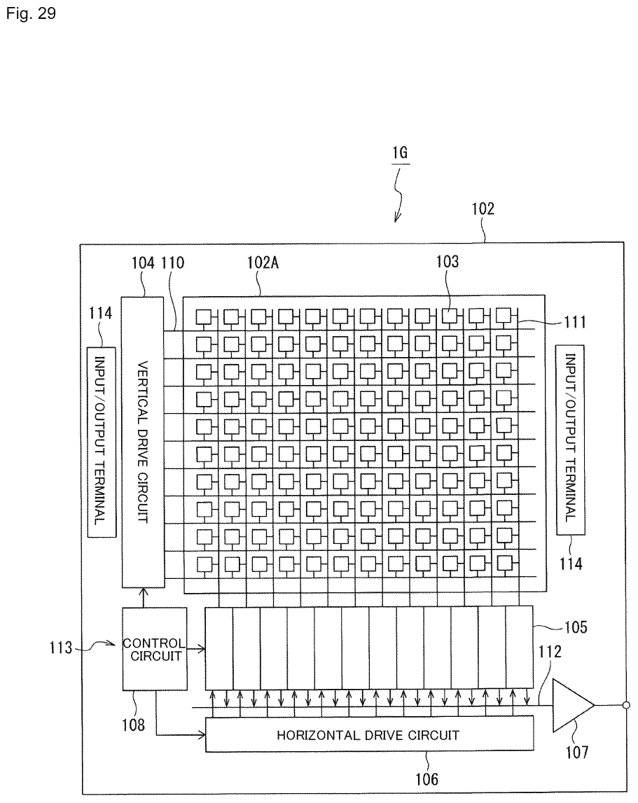

The semiconductor chip 102 includes a logic circuit 113 shown in FIG. 29. As shown in FIG. 29, the logic circuit 113 includes a vertical drive circuit 104, a column signal processing circuit 105, a horizontal drive circuit 106, an output circuit 107, a control circuit 108, and the like. The logic circuit 113 is configured with a CMOS (Complementary MOS) circuit having, for example, an n-channel conductivity-type MOSFET (Metal Oxide Semiconductor Field-effect transistor) and a p-channel conductivity-type MOSFET as field-effect transistors.

The vertical drive circuit 104 is configured with, for example, a shift register. The vertical drive circuit 104 sequentially selects desired pixel drive lines 110, supplies pulses for driving the pixels 103 to the selected pixel drive lines 110, and drives the pixels 103 row by row. That is, the vertical drive circuit 104 sequentially selectively scans each pixel 103 of the pixel array portion 102A in the vertical direction row by row, generates a signal charge generated by a photoelectric conversion unit (photoelectric conversion element) of each pixel 103 according to the amount of received light, and supplies the pixel signal from the pixel 103 based on the signal charge to the column signal processing circuit 105 through the vertical signal line 111.

The column signal processing circuit 105 is arranged for each column of pixels 103, for example, and performs signal processing such as noise removal on the signals output from one row of pixels 103 for each pixel column. For example, the column signal processing circuit 105 performs signal processing such as CDS (Correlated Double Sampling) and AD (Analog Digital) conversion to remove fixed pattern noise specific to pixels.

The horizontal drive circuit 106 is configured with, for example, a shift register. The horizontal drive circuit 106 sequentially selects the column signal processing circuits 105 by sequentially outputting horizontal scanning pulses to the column signal processing circuit 105 and outputs a pixel signal on which signal processing has been performed from the column signal processing circuits 105 to the horizontal signal line 112.

The output circuit 107 performs signal processing on the pixel signals sequentially supplied from the respective column signal processing circuits 105 through the horizontal signal line 112 and outputs resultant pixel signals. As the signal processing, for example, buffering, black level adjustment, a column deviation correction, various types of digital signal processing, and the like can be used.

The control circuit 108 generates a clock signal or a control signal as a reference for operations of the vertical drive circuit 104, the column signal processing circuit 105, the horizontal drive circuit 106, and the like based on a vertical synchronization signal, a horizontal synchronization signal, and a master clock signal. In addition, the control circuit 108 outputs the generated clock signal or control signal to the vertical drive circuit 104, the column signal processing circuit 105, the horizontal drive circuit 106, and the like.

### <Pixel Circuit Configuration>

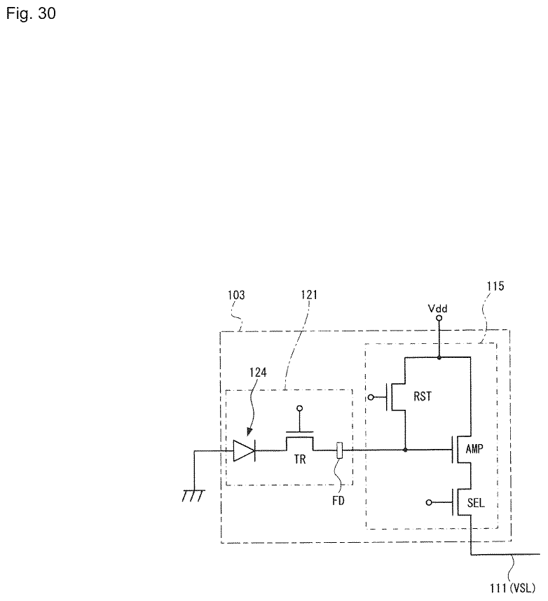

As shown in FIG. 30, each pixel 103 of the plurality of pixels 103 includes a photoelectric conversion region 121 and a readout circuit 115. The photoelectric conversion region 121 includes a photoelectric conversion unit 124, a transfer transistor TR, and a charge-holding region (floating diffusion) FD. The readout circuit 115 is electrically connected to the charge-holding region FD of the photoelectric conversion region 121. In the seventh embodiment, one readout circuit 115 is assigned to one pixel 103 as an example, but the circuit configuration is not limited to this, and one readout circuit 115 may be shared by a plurality of pixels 103.

The photoelectric conversion unit 124 shown in FIG. 30 is configured with, for example, a pn junction type photodiode (PD), and generates signal charges according to the amount of received light. The photoelectric conversion unit 124 has a cathode side electrically connected to the source region of the transfer transistor TR and an anode side electrically connected to a reference potential line (for example, ground).

The transfer transistor TR shown in FIG. 30 transfers signal charges photoelectrically converted by the photoelectric conversion unit 124 to the charge-holding region FD. The source region of the transfer transistor TR is electrically connected to the cathode side of the photoelectric conversion unit 124, and the drain region of the transfer transistor TR is electrically connected to the charge-holding region FD. The gate electrode of the transfer transistor TR is electrically connected to a transfer transistor drive line among the pixel drive lines 110 (see FIG. 29).

The charge-holding region FD shown in FIG. 30 temporarily holds (accumulates) the signal charges transferred from the photoelectric conversion unit 124 via the transfer transistor TR.

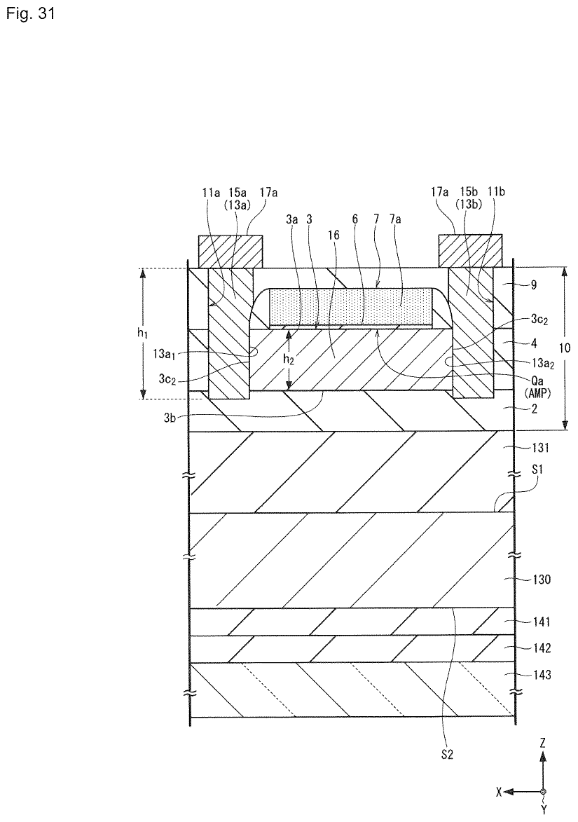

The photoelectric conversion region 121 including the photoelectric conversion unit 124, the transfer transistor TR, and the charge-holding region FD is mounted on a semiconductor layer 130 (see FIG. 31) as a second semiconductor layer to be described later.

The readout circuit 115 shown in FIG. 30 reads out the signal charge held in the charge-holding region FD and outputs a pixel signal based on this signal charge. The readout circuit 115 includes, but not limited to, an amplification transistor AMP, a selection transistor SEL, and a reset transistor RST as pixel transistors, for example. Each of these transistors (AMP, SEL, RST) and the above-described transfer transistor TR are configured with, for example, a MOSFET as a field-effect transistor. Moreover, MISFETs may be used as these transistors.

As shown in FIG. 30, the amplification transistor AMP has a source region electrically connected to a drain region of the selection transistor SEL and a drain region electrically connected to a power supply line Vdd and a drain region of the reset transistor RST. The gate electrode of the amplification transistor AMP is electrically connected to the charge-holding region FD and the source region of the reset transistor RST.

In the selection transistor SEL, a source region is electrically connected to the vertical signal line 111 (VSL), and a drain region is electrically connected to the source region of the amplification transistor AMP. A gate electrode of the selection transistor SEL is electrically connected to a selection transistor drive line among pixel drive lines 110 (see FIG. 2).

In the reset transistor RST, a source region is electrically connected to the charge-holding region FD and the gate electrode of the amplification transistor AMP, and a drain region is electrically connected to the power supply line Vdd and the drain region of the amplification transistor AMP. A gate electrode of the reset transistor RST is electrically connected to a reset transistor drive line among the pixel drive lines 110 (see FIG. 29).

When the transfer transistor TR is turned on, the transfer transistor TR transfers the signal charge generated by the photoelectric conversion unit 124 to the charge-holding region FD.

When the reset transistor RST is turned on, the reset transistor RST resets the potential (signal charge) of the charge-holding region FD to the potential of the power supply line Vdd. The selection transistor SEL controls the output timing of the pixel signal from the readout circuit 115.

The amplification transistor AMP generates, as a pixel signal, a voltage signal corresponding to the level of the signal charge held in the charge-holding region FD. The amplification transistor AMP forms a source follower-type amplifier and outputs a pixel signal with a voltage corresponding to the level of the signal charge generated by the photoelectric conversion unit 124. When the selection transistor SEL is turned on, the amplification transistor AMP amplifies the potential of the charge-holding region FD and outputs a voltage corresponding to the potential to the column signal processing circuit 105 via the vertical signal line 111 (VSL).

During the operation of the solid-state imaging device 1G according to the seventh embodiment, signal charges generated by the photoelectric conversion unit 124 of the pixel 103 are held (accumulated) in the charge-holding region FD via the transfer transistor TR of the pixel 103. The signal charges held in the charge-holding region FD are read out by the readout circuit 115 and applied to the gate electrode of the amplification transistor AMP of the readout circuit 115. A horizontal line selection control signal is applied to the gate electrode of the selection transistor SEL of the readout circuit 115 from the vertical shift register. By setting the selection control signal to a high (H) level, the selection transistor SEL becomes conductive, and a current corresponding to the potential of the charge-holding region FD amplified by the amplification transistor AMP flows to the vertical signal line 111. Further, by setting the reset control signal applied to the gate electrode of the reset transistor RST of the readout circuit 115 to a high (H) level, the reset transistor RST becomes conductive and resets the signal charge accumulated in the charge-holding region FD.

Note that the selection transistor SEL may be omitted if necessary. When the selection transistor SEL is omitted, the source region of the amplification transistor AMP is electrically connected to the vertical signal line 111 (VSL).

### <<Vertical Cross-Sectional Structure of Solid-State Imaging Device>>

Next, the vertical cross-sectional structure of the semiconductor chip 102 (solid-state imaging device 1G) will be described using FIG. 31. FIG. 31 is a schematic vertical cross-sectional view showing the vertical cross-sectional structure of the pixel array portion in FIG. 28, and the top and bottom are reversed with respect to FIG. 28 to make the drawing easier to see.

### <Semiconductor Chip>

As shown in FIG. 31, the semiconductor chip 102 includes a semiconductor layer 130 having a first surface S1 and a second surface S2 located on opposite sides in the thickness direction (Z direction), an insulating layer 131 provided on the first surface S1 side of the semiconductor layer 130, and an insulating layer 10 provided on the opposite side of the insulating layer 131 from the semiconductor layer 130 side.

Further, the semiconductor chip 102 includes, on the second surface S2 side of the semiconductor layer 130, a planarization layer 141, a color filter layer 142, a lens layer 143, and the like, which are sequentially stacked from the second surface S2 side.

The semiconductor layer 130 is made of, for example, single-crystal silicon. The planarization layer 141 is made of, for example, a silicon oxide film. The planarization layer 141 covers the entire second surface S2 of the semiconductor layer 130 in the pixel array portion 2A so that the second surface S2 (light incident surface) side of the semiconductor layer 130 becomes a flat surface without unevenness.

In the color filter layer 142, color filters of red (R), green (G), and blue (B) are provided for each pixel 103, and color-separates the incident light incident from the light incident surface side of the semiconductor chip 102.

The lens layer 143 is provided with a microlens for each pixel 103 that condenses the illumination light and allows the condensed light to enter the photoelectric conversion region 121 efficiently.

As shown in FIG. 31, the insulating layer 10 of this seventh embodiment has the same configuration as the insulating layer 10 of the above-described first embodiment shown in FIG. 2 and includes a semiconductor layer 3 and a field-effect transistor Qa having a channel forming portion 16 provided in the semiconductor layer 3.

Here, in this seventh embodiment, the semiconductor layer 3 corresponds to a specific example of the “first semiconductor layer” of the present technology, and the semiconductor layer 130 corresponds to a specific example of the “second semiconductor layer” of the present technology.

The semiconductor layer 130 is arranged above or below the semiconductor layer 3. In this seventh embodiment, the semiconductor layer 130 is arranged below the semiconductor layer 3. That is, the semiconductor chip 102 has a two-step structure in which the semiconductor layer 130 and the semiconductor layer 3 are stacked in the thickness direction (Z direction).

In the seventh embodiment, the photoelectric conversion unit 124, the transfer transistor TR, and the charge-holding region FD shown in FIG. 30 are provided in the semiconductor layer 130 shown in FIG. 31. On the other hand, the pixel transistors (AMP, SEL, RST) included in the readout circuit 115 shown in FIG. 30 are configured with the field effect transistor Qa shown in FIG. 31. FIG. 31 shows, as an example, the amplification transistor AMP configured with a field-effect transistor Qa.

In the solid-state imaging device 1G according to the seventh embodiment, the pixel transistors (AMP, SEL, RST) included in the readout circuit 115 are configured with a field effect transistor Qa.

Therefore, in the solid-state imaging device 1G according to the seventh embodiment, the same effects as in the semiconductor device 1A according to the above-described first embodiment are obtained.

Furthermore, when the photoelectric conversion unit 124, the transfer transistor TR, and the charge-holding region FD are formed in the semiconductor layer 130, and the semiconductor layer 3 is stacked on the semiconductor layer 130 to form the field-effect transistor Qa, the activation annealing of the pair of main electrode regions can be omitted. Thus, the thermal budget (thermal history) can be reduced, and the influence on the photoelectric conversion unit 124, the transfer transistor TR, the charge-holding region FD, and the like provided in the semiconductor layer 130 can be suppressed.

Note that at least one of the pixel transistors (AMP, SEL, RST) included in the readout circuit 115 may be configured with a field effect transistor Qa.

In addition, the pixel transistors (AMP, SEL, RST) included in the readout circuit 115 may be configured with either, the field effect transistor Qb shown in FIG. 14 of the above-described second embodiment, the field effect transistor Qc shown in FIG. 19 of the above-described third embodiment, the field-effect transistor Qd shown in FIG. 23 of the above-described fourth embodiment, the field-effect transistor Qe shown in FIG. 26 of the above-described fifth embodiment, or the field-effect transistor Qf shown in FIG. 27 of the above-described sixth embodiment.

### Eighth Embodiment

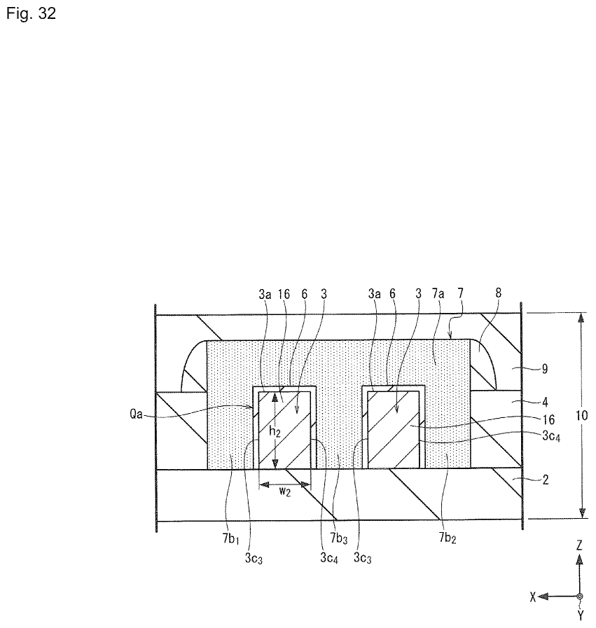

In the first to seventh embodiments described above, the gate electrode 7 including the head portion 7a and the two leg portions 7b₁ and 7b₂ has been described. However, the number of leg portions of the gate electrode 7 is not limited to two, and as shown in FIG. 32, the gate electrode 7 may include three leg portions 7b₁, 7b₂, and 7b₃. Although not shown, the gate electrode 7 may include four or more leg portions. In this case, the number of semiconductor layers 3 is n−1, where n is the number of leg portions of the gate electrode 7. Even in this case, the present technology can be applied. In FIG. 32, a field effect transistor Qa is illustrated as an example.

### Ninth Embodiment

### <<Example of Application to Electronic Device>>

The present technology (technology according to the present disclosure) can be applied to various electronic devices, such as imaging devices such as digital still cameras and digital video cameras, mobile phones with an imaging function, or other devices with an imaging function.

FIG. 33 is a diagram showing a schematic configuration of an electronic device (for example, a camera) according to a ninth embodiment of the present technology.

As shown in FIG. 33, an electronic device 200 includes a solid-state imaging device 201, an optical lens 202, a shutter device 203, a drive circuit 204, and a signal processing circuit 205. This electronic device 200 shows an embodiment in which the solid-state imaging device 1G according to the seventh embodiment of the present technology is used in an electronic device (for example, a camera) as the solid-state imaging device 201.

The optical lens 202 forms an image of the image light (incident light 206) from the subject onto the imaging surface of the solid-state imaging device 201. As a result, signal charges are accumulated in the solid-state imaging device 201 for a certain period of time. The shutter device 203 controls the light illumination period and the light blocking period to the solid-state imaging device 201. The drive circuit 204 supplies drive signals that control the transfer operation of the solid-state imaging device 201 and the shutter operation of the shutter device 203. Signal transfer of the solid-state imaging device 201 is performed according to a drive signal (timing signal) supplied from the drive circuit 204. The signal processing circuit 205 performs various signal processing on the signals (pixel signals) output from the solid-state imaging device 201. An image signal having been subjected to signal processing is stored in a storage medium such as a memory or output to a monitor.

With such a configuration, in the electronic device 200 of the ninth embodiment, the occurrence of a short-channel effect in the solid-state imaging device 201 is suppressed, and thus, image quality can be improved.

Note that the electronic device 200 to which the solid-state imaging device of the above-described embodiment can be applied is not limited to a camera, but can also be applied to other electronic devices. For example, the electronic device 200 may be applied to an imaging device such as a camera module for a mobile device such as a mobile phone or a tablet terminal.

In addition to the solid-state imaging device as the image sensor described above, the present technology can be applied to general light detection devices, including distance sensors called ToF (Time of Flight) sensors that measure distance. A distance sensor is a sensor that emits illumination light toward an object, detects the reflected light that is reflected from the object's surface, measures the flight time from when the illumination light is emitted until the reflected light is received, and calculates the distance to the object based on the flight time. As the structure of the element isolation region of this distance sensor, the structure of the element isolation region described above can be adopted.

### Other Embodiments

In the first to seventh embodiments described above, field-effect transistors Qa to Qf have been described in which the channel forming portion 16 is provided in the rectangular parallelepiped semiconductor layer 3 extending in the X direction. However, the present technology is not limited to the rectangular parallelepiped semiconductor layer 3.

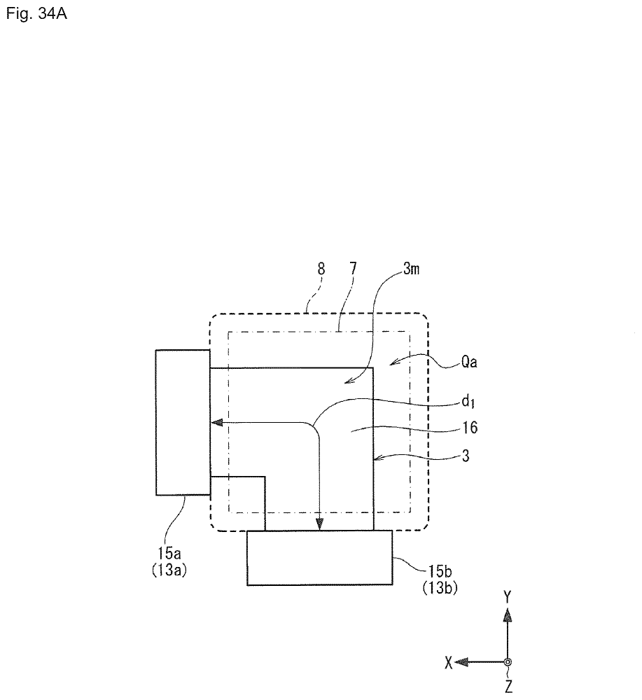

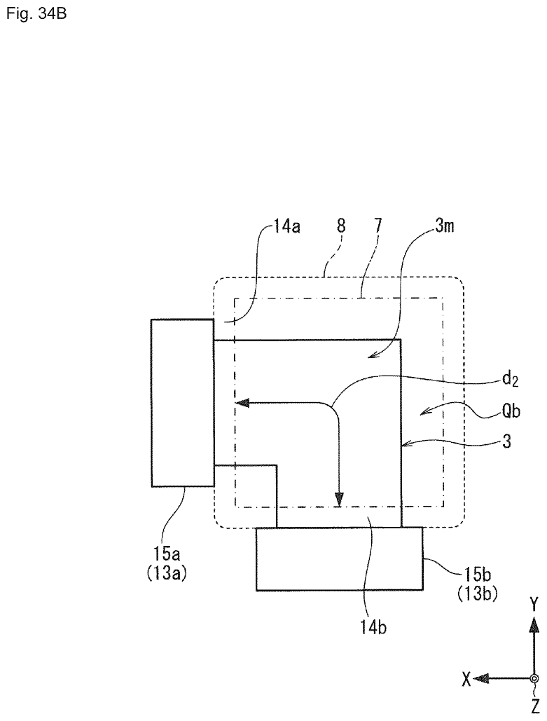

For example, as shown in FIG. 34A, the present technology can be applied to a field-effect transistor Qa in which the channel forming portion 16 and the gate electrode 7 are provided in a corner portion 3m of a semiconductor layer 3 having an L-shaped planar shape. In this case, the distance d₁ between the pair of main electrode regions 15a and 15b includes a distance along the X direction and a distance along the Y direction. The channel length further includes a distance along the X direction and a distance along the Y direction. The semiconductor layer 3 includes a first portion extending in the X direction and a second portion extending in the Y direction from one end side of the first portion.

Further, as shown in FIG. 34B, the present technology can be applied to a field-effect transistor Qb in which the channel forming portion 16 and the gate electrode 7 are provided at a corner portion 3m of a semiconductor layer 3 having an L-shaped planar shape. In this case, the distance de between the pair of channel-forming regions 14a and 14b includes a distance along the X direction and a distance along the Y direction. The channel length further includes a distance along the X direction and a distance along the Y direction. The semiconductor layer 3 includes a first portion extending in the X direction and a second portion extending in the Y direction from one end side of the first portion.

Further, although not shown, the present technique can also be applied to a case where field-effect transistors Qc, Qd, Qe, and Qf are arranged at the corner portion 3m of the semiconductor layer 3.

Further, although not shown, the present technology can also be applied to a field-effect transistor in which a gate electrode is provided over the upper surface portion and the side surface portions of a protrusion formed by etching a semiconductor layer.

Note that the present technology may have the following configuration.

(1)

A semiconductor device including:
a semiconductor layer having an upper surface portion, a lower surface portion, and a side surface portion; and
a field-effect transistor in which a channel forming portion is provided in the semiconductor layer,
the field-effect transistor including:
a gate electrode provided in the channel forming portion of the semiconductor layer over the upper surface portion and the side surface portion of the semiconductor layer with a gate insulating film interposed therebetween; and
a pair of main electrode regions provided on an outer side of the semiconductor layer in a channel length direction of the channel forming portion and separated from each other with the channel forming portion interposed therebetween,
wherein
each of the pair of main electrode regions includes a conductor layer that is provided in contact with the side surface portion of the semiconductor layer and that is in a layer different from the semiconductor layer.
   (2)

The semiconductor device according to (1), wherein
the conductor layer is in contact with the semiconductor layer from the upper surface portion side to the lower surface portion side of the side surface portion of the semiconductor layer.
   (3)

The semiconductor device according to (1) or (2), wherein
the conductor layer has a different crystallinity from that of the semiconductor layer.
   (4)

The semiconductor device according to any one of (1) to (4), wherein
the conductor layer is an amorphous or polycrystalline semiconductor film doped with impurities.
   (5)

The semiconductor device according to (1) or (2), wherein
the conductor layer is an epitaxial layer covalently bonded to the semiconductor layer and doped with impurities.
   (6)

The semiconductor device according to any one of (1) to (5), wherein
a width of the conductor layer in a channel width direction of the channel forming portion is wider than a width of the semiconductor layer.
   (7)

The semiconductor device according to any one of (1) to (6), wherein
the conductor layer protrudes further downward than the lower surface portion of the semiconductor layer.
   (8)

The semiconductor device according to any one of (1) to (7), wherein
the conductor layer protrudes further upward than the upper surface portion of the semiconductor layer.
   (9)

The semiconductor device according to any one of (1) to (8), wherein
a thickness of the conductor layer is thicker than the semiconductor layer.
   (10)

The semiconductor device according to any one of (4) to (9), wherein
an impurity concentration of the conductor layer is 1E+17 cm⁻³ or more on the same side as the lower surface portion of the semiconductor layer.
   (11)

The semiconductor device according to any one of (1) to (10), wherein
the field-effect transistor further includes a pair of extension regions formed of a semiconductor region, provided in contact with the conductor layer on both end sides of the semiconductor layer with the channel forming portion interposed therebetween.
   (12)

The semiconductor device according to any one of (4) to (10), wherein
the field-effect transistor further includes a pair of extension regions formed of a semiconductor region, provided in contact with the conductor layer on both end sides of the semiconductor layer with the channel forming portion interposed therebetween, and
an impurity concentration of each of the pair of extension regions is higher than an impurity concentration of the channel forming portion and lower than an impurity concentration of the conductor layer.
   (13)

The semiconductor device according to any one of (1) to (12), wherein
the field-effect transistor further includes a sidewall spacer provided on a sidewall of the gate electrode, and
a boundary portion between the conductor layer and the semiconductor layer overlaps the sidewall spacer in plan view.
   (14)

The semiconductor device according to any one of (1) to (12), wherein
the field-effect transistor further includes a sidewall spacer provided on a sidewall of the gate electrode, and
a boundary portion between the conductor layer and the conductor layer is located on an outer side of the sidewall spacer in plan view.
   (15)

The semiconductor device according to any one of (1) to (14), wherein
a thickness of the semiconductor layer is thicker than the channel length.
   (16)

The semiconductor device according to any one of (1) to (14), further including:
an insulating layer including an insulating film provided on the lower surface portion side of the semiconductor layer, wherein
the insulating layer includes the semiconductor layer and the field-effect transistor, and
the conductor layer is provided in a dug portion of the insulating layer.
   (17)

The semiconductor device according to any one of (1) to (16), further including:
a photoelectric conversion element; and
a readout circuit that reads out signal charges photoelectrically converted by the photoelectric conversion element, wherein
at least one of a plurality of transistors included in the readout circuit is configured with the field-effect transistor.
   (18)

The semiconductor device according to (17), further including:
the semiconductor layer as a first semiconductor layer; and
a second semiconductor layer disposed above or below the first semiconductor layer and provided with the photoelectric conversion element.
   (19)

An electronic device including:
a semiconductor device;
an optical lens that forms an image of image light from a subject onto an imaging surface of the semiconductor device; and
a signal processing circuit that performs signal processing on signals output from the semiconductor layer,
the semiconductor device including:
a semiconductor layer having an upper surface portion, a lower surface portion, and a side surface portion; and
a field-effect transistor in which a channel forming portion is provided in the semiconductor layer, the field-effect transistor including:
a gate electrode provided in the channel forming portion of the semiconductor layer over the upper surface portion and the side surface portion of the semiconductor layer with a gate insulating film interposed therebetween; and
a pair of main electrode regions provided on an outer side of the semiconductor layer in a channel length direction of the channel forming portion and separated from each other with the channel forming portion interposed therebetween,
wherein
each of the pair of main electrode regions includes a conductor layer that is provided in contact with the side surface portion of the semiconductor layer and that is in a layer different from the semiconductor layer.

The scope of the present technology is not limited to the illustrated and described exemplary embodiments, but includes all embodiments that provide equivalent effects sought after with the present technology. In addition, the scope of the present technology is not limited to combinations of features of the invention defined by the claims, but can be defined by any desired combination of specific features among all disclosed features.

### REFERENCE SIGNS LIST

1A, 1B, 1C, 1D, 1E, 1F Semiconductor device
1G Solid-state imaging device
2 First insulating film (base insulating film)
3 Semiconductor layer (first semiconductor layer)
3a Upper surface portion
3b Lower surface portion
3c₁, 3c₂, 3c₃, 3c₄ Side surface portion
4 Second insulating film (surrounding insulating film)
5 Dug portion (dug portion for gate electrode)
6 Gate insulating film
7 Gate electrode
7a Head portion (first portion)
7b₁, 7b₂, 7b₃ Leg portion (second portion)
8 Sidewall spacer
9 Third insulating film (covering insulating film)
10 Insulating layer (inclusive insulating layer)
11a, 11b Dug portion (main electrode dug portion)
13a, 13b Semiconductor film (conductor layer)
13a₁, 13b₁ Boundary portion
14a, 14b Extension region
15a, 15b Main electrode region
16 Channel forming portion (channel region)
17a, 17b Wiring
19a, 19b Main electrode region
21a, 21b Main electrode region
22a, 22b Epitaxial growth layer
23a, 23b Filling layer
102 Semiconductor chip
102A Pixel array portion
102B Peripheral portion
103 Pixel
104 Vertical drive circuit
105 Column signal processing circuit
106 Horizontal drive circuit
107 Output circuit
108 Control circuit
110 Pixel drive line
111 Vertical signal line
113 Logic circuit
114 Bonding pad
115 Readout circuit
130 Semiconductor layer (second semiconductor layer)
131 Wiring layer
141 Planarization layer
142 Filter layer
143 Lens layer
200 Electronic device
201 Solid-state imaging device
202 Optical lens
203 Shutter device
204 Drive circuit
205 Signal processing circuit
206 Incident light

1. A semiconductor device comprising:
a semiconductor layer having an upper surface portion, a lower surface portion, and a side surface portion; and
a field-effect transistor in which a channel forming portion is provided in the semiconductor layer,
the field-effect transistor including:
a gate electrode provided in the channel forming portion of the semiconductor layer over the upper surface portion and the side surface portion of the semiconductor layer with a gate insulating film interposed therebetween; and
a pair of main electrode regions provided on an outer side of the semiconductor layer in a channel length direction of the channel forming portion and separated from each other with the channel forming portion interposed therebetween, wherein
each of the pair of main electrode regions includes a conductor layer that is provided in contact with the side surface portion of the semiconductor layer and that is in a layer different from the semiconductor layer.

2. The semiconductor device according to claim 1, wherein
the conductor layer is in contact with the semiconductor layer from the upper surface portion side to the lower surface portion side of the side surface portion of the semiconductor layer.

3. The semiconductor device according to claim 1, wherein
the conductor layer has a different crystallinity from that of the semiconductor layer.

4. The semiconductor device according to claim 1, wherein
the conductor layer is an amorphous or polycrystalline semiconductor film doped with impurities.

5. The semiconductor device according to claim 1, wherein
the conductor layer is an epitaxial layer covalently bonded to the semiconductor layer and doped with impurities.

6. The semiconductor device according to claim 1, wherein
a width of the conductor layer in a channel width direction of the channel forming portion is wider than a width of the semiconductor layer.

7. The semiconductor device according to claim 1, wherein
the conductor layer protrudes further downward than the lower surface portion of the semiconductor layer.

8. The semiconductor device according to claim 1, wherein
the conductor layer protrudes further upward than the upper surface portion of the semiconductor layer.

9. The semiconductor device according to claim 1, wherein
a thickness of the conductor layer is thicker than the semiconductor layer.

10. The semiconductor device according to claim 1, wherein
an impurity concentration of the conductor layer is 1E+17 cm-3 or more on the same side as the lower surface portion of the semiconductor layer.

11. The semiconductor device according to claim 1, wherein
the field-effect transistor further includes a pair of extension regions formed of a semiconductor region, provided in contact with the conductor layer on both end sides of the semiconductor layer with the channel forming portion interposed therebetween.

12. The semiconductor device according to claim 1, wherein
the field-effect transistor further includes a pair of extension regions formed of a semiconductor region, provided in contact with the conductor layer on both end sides of the semiconductor layer with the channel forming portion interposed therebetween, and an impurity concentration of each of the pair of extension regions is higher than an impurity concentration of the channel forming portion and lower than an impurity concentration of the conductor layer.

13. The semiconductor device according to claim 1, wherein
the field-effect transistor further includes a sidewall spacer provided on a sidewall of the gate electrode, and
a boundary portion between the conductor layer and the semiconductor layer overlaps the sidewall spacer in plan view.

14. The semiconductor device according to claim 1, wherein
the field-effect transistor further includes a sidewall spacer provided on a sidewall of the gate electrode, and
a boundary portion between the conductor layer and the conductor layer is located on an outer side of the sidewall spacer in plan view.

15. The semiconductor device according to claim 1, wherein
a thickness of the semiconductor layer is thicker than the channel length.

16. The semiconductor device according to claim 1, further comprising:
an insulating layer including an insulating film provided on the lower surface portion side of the semiconductor layer, wherein
the insulating layer includes the semiconductor layer and the field-effect transistor, and
the conductor layer is provided in a dug portion of the insulating layer.

17. The semiconductor device according to claim 1, further comprising:
a photoelectric conversion element; and
a readout circuit that reads out signal charges photoelectrically converted by the photoelectric conversion element, wherein
at least one of a plurality of transistors included in the readout circuit is configured with the field-effect transistor.

18. The semiconductor device according to claim 17, further comprising:
the semiconductor layer as a first semiconductor layer; and
a second semiconductor layer disposed above or below the first semiconductor layer and provided with the photoelectric conversion element.

19. An electronic device comprising:
a semiconductor device;
an optical lens that forms an image of image light from a subject onto an imaging surface of the semiconductor device; and
a signal processing circuit that performs signal processing on signals output from the semiconductor layer,
the semiconductor device including:
a semiconductor layer having an upper surface portion, a lower surface portion, and a side surface portion; and
a field-effect transistor in which a channel forming portion is provided in the semiconductor layer,
the field-effect transistor including:
a gate electrode provided in the channel forming portion of the semiconductor layer over the upper surface portion and the side surface portion of the semiconductor layer with a gate insulating film interposed therebetween; and
a pair of main electrode regions provided on an outer side of the semiconductor layer in a channel length direction of the channel forming portion and separated from each other with the channel forming portion interposed therebetween, wherein
each of the pair of main electrode regions includes a conductor layer that is provided in contact with the side surface portion of the semiconductor layer and that is in a layer different from the semiconductor layer.
